(19) United States
(12) Patent Application Publication
(10) Pub. No.: US 2011/0273197 A1
(43) Pub. Date: Nov. 10, 2011

(54) SIGNAL GENERATOR FOR A BUILT-IN SELF TEST

(75) Inventors: Gaurab Banerjee, Bangalore (IN); Manas Behera, Austin, TX (US)

(73) Assignee: QUALCOMM INCORPORATED, San Diego, CA (US)

(21) Appl. No.: 12/776,168

(22) Filed: May 7, 2010

(51) Int. Cl. G01R 31/3187; G01M 19/00

(52) U.S. Cl. 324/750.3; 702/124

(57) ABSTRACT

An integrated circuit with Built-in Self Test (BiST) is described. The integrated circuit includes a signal generator used to perform a BiST on the integrated circuit. The integrated circuit also includes a local oscillator used by the signal generator to generate one or more test signals used to perform the BiST on the integrated circuit.

### TECHNICAL FIELD

The present disclosure relates generally to electronic devices for communication systems. More specifically, the present disclosure relates to a signal generator for a built-in self test.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

As the complexity of digital circuits has increased, a need to test the digital circuits has also increased. Testing may be used to verify or test various parts of devices, such as pieces of hardware, software or a combination of both. This testing may be very beneficial. For example, a manufacturer may desire to test complex integrated circuits in a product before shipping it. However, testing complex digital circuits has become increasingly expensive as the complexity and specialty of circuits have increased. Thus, there is a need for systems and methods that will allow less expensive testing of complex integrated circuits.

However, in many cases the equipment used to test a device is a separate piece of equipment than the device being tested. Some testing that takes place is performed substantially by the test equipment. Thus, benefits may be realized by providing improved systems and methods for providing built-in self tests for electronic devices and/or components used in electronic devices.

### BRIEF DESCRIPTION OF THE DRAWINGS

FIG. 1 shows a system for production testing of a device under test (DUT) with mixed signal circuitry;

FIG. 2 is a block diagram illustrating various components of one configuration of a built-in self test (BiST) system;

FIG. 3 is a block diagram illustrating a BiST system for use in the present systems and methods;

FIG. 4 is a flow diagram illustrating a method for providing a BiST of mixed signal integrated circuits;

FIG. 5 is a block diagram illustrating one configuration of a signal generator in a BiST system;

FIG. 6 is a block diagram illustrating a more specific example of a DUT;

FIG. 7 is a block diagram illustrating possible functionality in one configuration of a signal generator;

FIG. 8 is a block diagram illustrating one specific configuration of a signal generator;

FIG. 9 is a block diagram illustrating more detail of one configuration of a mixer/adder module;

FIG. 10 is a block diagram illustrating more detail of the functionality of one configuration of a mixer/adder module;

FIG. 11 is a flow diagram illustrating one configuration of a method for generating signals for a built-in self test;

FIG. 12 is a block diagram illustrating a BiST system;

FIG. 13 is a flow diagram illustrating another method for providing a BiST of mixed signal circuitry;

FIG. 14 is a block diagram illustrating an embedded sensor for use in the present systems and methods;

FIG. 15 is a block diagram illustrating another embedded sensor for use in the present systems and methods;

FIG. 16 is a circuit diagram illustrating a switch for use in an embedded sensor; and

FIG. 17 illustrates certain components that may be included within a wireless device.

### DETAILED DESCRIPTION

An integrated circuit with Built-in Self Test (BiST) is disclosed. The integrated circuit includes a signal generator that is used to perform a BiST on the integrated circuit. A local oscillator is also included on the integrated circuit that is used by the signal generator to generate one or more test signals used to perform the BiST on the integrated circuit.

The local oscillator may include a frequency synthesizer used for functions other than BiST functions on the integrated circuit. The local oscillator may include a radio frequency (RF) synthesizer used for RF transceiver functions. The signal generator may include one or more frequency dividers. The frequency dividers may generate differential quadrature signals (I, I−, Q, Q−) in one or more frequency bands.

The one or more frequency dividers may be included in a high frequency divider array and a low frequency divider array. The high frequency divider array may divide the frequency of a local oscillator signal and the low frequency divider array may divide the frequency of an external signal. The local oscillator signal may be at a higher frequency than the external signal.

The signal generator may also include one or more mixers and a summer. The one or more mixers may mix two or more signals to generate one or more test signals. The two or more signals mixed may be selected from a group consisting of one or more signals based on a local oscillator signal and one or more signals based on an external signal. The external signal may be a digital clock reference signal.

One or more of the local oscillator signals may be divided in frequency. One or more of the external signals may be divided in frequency. The two or more signals to be mixed may be selected by one or more multiplexers included in the integrated circuit.

The amplitude of the one or more test signals may be adjusted by an amplifier/attenuator module included in the integrated circuit. The two or more signals may be selected and mixed in order to produce frequency variation in the one or more test signals. The frequency variation may be a frequency sweep over a given range of frequencies.

The two or more signals may be selected and mixed in order to produce a frequency offset from the local oscillator signal in the one or more test signals. The frequency offset in the one or more test signals may be used to conduct down-conversion measurements.

The amplitude of the one or more test signals may be varied to produce an amplitude sweep in the one or more test signals. The amplitude sweep may be selected from the group consisting of a linear amplitude sweep and a logarithmic amplitude sweep. The amplitude of the one or more test signals may be varied to produce an offset in differential outputs between two or more test signals. The offset in differential outputs between the two or more test signals may be used to measure one or more circuit imbalances.

The two or more signals may be selected and mixed in order to produce test signals that are two-tone signals. The one or more test signals may be used to conduct third-order input intercept point (IIP3) measurements.

The two or more signals may be selected and mixed in order to generate a test signal selected from the group consisting of: an upper sideband (USB) signal, a lower sideband (LSB) signal, a double sideband signal (DSB) and a double sideband-suppressed carrier (DSB-SC) signal. The one or more test signals may be differential output signals.

A method for generating signals for a Built-in Self Test (BiST) is also disclosed. The method includes generating a local oscillator signal on an integrated circuit, receiving an external signal and mixing two or more signals to generate one or more test signals for a BiST on an integrated circuit.

A computer-program product for generating signals for a Built-in Self Test (BiST) is also disclosed. The computer-program product includes a non-transitory computer-readable medium with instructions. The instructions include code for generating a local oscillator signal, code for receiving an external signal, and code for mixing two or more signals to generate one or more test signals.

An apparatus for generating signals for a Built-in Self Test (BiST) is also disclosed. The apparatus includes means for generating a local oscillator signal, means for receiving an external signal and means for mixing two or more signals to generate one or more test signals.

Many different kinds of electronic devices may benefit from testing. Different kinds of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “mobile station” refers to an electronic device that may be used for voice and/or data communication over a wireless communication network. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc.

A wireless communication network may provide communication for a number of mobile stations, each of which may be serviced by a base station. A base station may alternatively be referred to as an access point, a Node B, or some other terminology. Base stations and mobile stations may make use of integrated circuits with mixed signal circuitry. However, many different kinds of electronic devices, in addition to the wireless devices mentioned, may make use of integrated circuits with mixed signal circuitry. Production of integrated circuits may result in process variations that affect the operation of the mixed signal circuitry. Accordingly, a broad array of electronic devices may benefit from the systems and methods disclosed herein.

Production testing of semiconductor devices typically involves the optimization of maintaining test quality to ensure a low defect rate in the final product while minimizing the overall test cost. Various matrices may be defined for test quality and the corresponding defect rates, which need to be adhered to with the available resources. Low cost testers have been developed in order to reduce test costs by downgrading Automatic Test Equipment (ATE) hardware resources. Providing voltage and timing resources for each pin on an ATE is one factor driving up the cost of ATE systems.

Some lower-cost ATEs attempt to minimize per pin hardware and provide a limited number of resource intensive pins for running hardware intensive tests. This approach may add constraints to test board design as well as multi-site testing, as the limited number of ATE resources may need to be allocated to multiple device-under-test (DUT) pins. With a Built-in Self Test (BiST) scheme, lower-cost ATEs may be sufficient for analog testing, which can substantially reduce the cost of testing.

Parallel testing has been enabled earlier in the product development cycle. Quad (or N-site) testing can be enabled when only power/ground and temperature compensated crystal oscillator (TCXO) connections are required (e.g., although more connections may optionally be used with the systems and methods herein). This can also substantially reduce test-cost. In the disclosed BiST scheme, a reduction in mixed-signal test time has been achieved by using a digital approach, wherein only power/ground and TCXO connections may be used. This allows multi-site testing of analog and mixed signal circuits since the approach is digital.

The high-volume testing of analog and radio frequency (RF) integrated circuits may require the use of external instrumentation with high accuracy. However, access issues with such instrumentation may increase the test time. Furthermore, a limited number of nodes can be probed for parameters of interest. The use of a BiST scheme may reduce both the test time and the resulting product development cost. For example, the BiST system may use correlation to perform the measurements such that an instrumentation grade signal source may not be required.

An on-chip housekeeping analog-to-digital converter (ADC) may be used for a multitude of housekeeping operations to provide a fully digital output. An on-chip ADC may be present on a large percentage of System on a Chip (SoC) and System in a Package (SiP) modules. The BiST scheme may employ an interval-sampling scheme for high data rates that an on-chip ADC may not have the ability to handle. The statistical parameters of a Gaussian distribution may be verified to ensure that no information is lost and no artifacts are created by the BiST scheme. By reusing housekeeping ADCs and microprocessors (such as ARM) cores, the BiST scheme can be enabled without additional area requirements on the chip. Such a piggybacked operation may save die area on the chip.

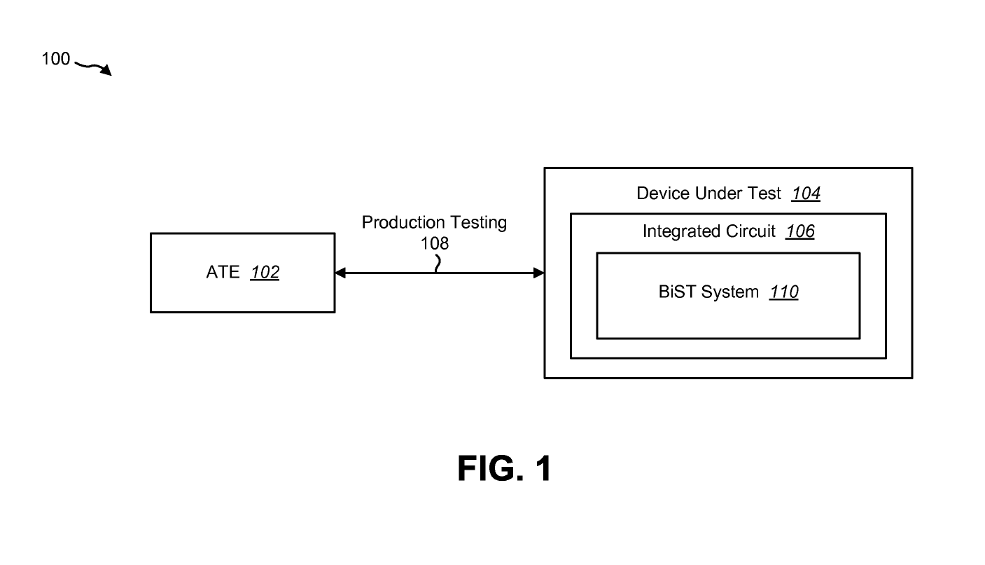

FIG. 1 shows a system 100 for production testing 108 of a device under test (DUT) 104 with mixed signal circuitry. In one configuration, the DUT 104 may be a wireless device such as a mobile station or a base station. Alternatively, the DUT 104 may be a chip for use in a wireless device. In other configurations, the DUT 104 may not be a wireless device or part of a wireless device. The DUT 104 may include an integrated circuit 106. The integrated circuit 106 may include mixed signal circuitry. Mixed signal circuitry may be circuitry that includes both analog and digital circuitry. Examples of integrated circuits that may be tested include baseband filters, amplifiers, mixers, phase locked loops (PLLs), oscillators, data convertors and bandpass filters.

The cost of testing mixed signal circuitry with a conventional analog-stimulus may be much higher than the cost of testing digital circuitry due to the higher cost of automated testing equipment (ATE) 102 required for analog stimulus generation. Multiple variants of low cost testers have been developed for digital testing which rely on relaxed timing, power or tester channel requirements to lower hardware costs. An ATE 102 may be unable to test integrated circuits 106 including mixed-signal/RF components due to the limitations of such ATE 102 (e.g., the lack of analog/RF stimulus and measurement modules). Analog blocks are increasingly common on digital Application Specific Integrated Circuits (ASICs), System on a Chip (SoC) and System in a Package (SiP) modules.

A digital ATE 102 may enable full production-quality testing 108 of integrated circuits 106 by using a Built-in Self Testing (BiST) system 110. The BiST system 110 may use a distributed network of sensors embedded on the integrated circuit 106 to perform measurements for parameters of interest. For example, the sensors may measure direct current (DC) and RF/alternating current (AC) amplitudes. The sensors may be connected to various blocks of interest within the integrated circuit 106 such as a low noise amplifier (LNA), a mixer, etc. The sensors may make measurements on the integrated circuit 106 at one or more internal nodes. The BiST system 110 may provide a fully digital output to ensure compatibility with non-analog low-cost ATE 102 and the ability to potentially reuse some of the hardware that the SoC/SiP may already have. The BiST system 110 may use on-die signal generation and data conversion.

The data measured by the sensors may be correlated by an ATE 102 with data gathered from external high-accuracy measurements. Once the two types of data have been correlated, the BiST based measurements may be used to determine if the integrated circuit 106 passes or fails certain figures of merit. It may then be determined whether the DUT 104 can be shipped to customers. Once BiST based tests are correlated to ATE based tests, a significant reduction in test time may be expected, due to the parallel nature of on-chip BiST based testing. In one configuration, the BiST system 110 may be disabled before shipping to customers.

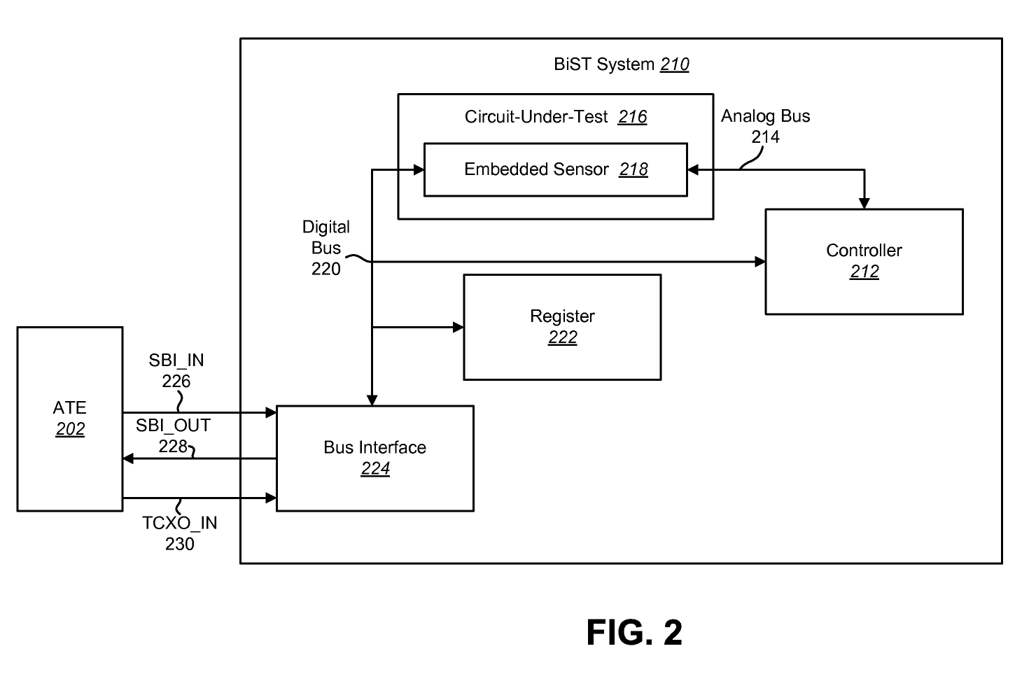

FIG. 2 is a block diagram illustrating various components of one configuration of a BiST system 210. The BiST system 210 of FIG. 2 may be one example of the BiST system 110 of FIG. 1. Access to the BiST system 210 may be accomplished through a bus interface 224. The bus interface 224 may be a serial bus interface (SBI). An ATE 202 may send an SBI_IN 226 signal to the BiST system 210 and receive an SBI_OUT 228 signal from the BiST system 210. A clocking signal such as a temperature compensated crystal oscillator (TCXO) may be provided to the BiST system 210 through a TCXO_IN 230. SBI_IN 226, SBI_OUT 228 and TCXO_IN 230 may all be provided to the BiST system 210 through the bus interface 224. Thus, changes to the existing input/output (I/O) scheme of the integrated circuit 106 may be unnecessary.

The bus interface 224 may provide access to a digital bus 220. The digital bus 220 may be a standard feature on a DUT 104. For example, a digital bus 220 is typically used in analog and mixed signal protocols. The digital bus 220 may provide digital logic for a register 222 and a controller 212 on the BiST system 210. The digital bus 220 may also provide digital logic for one or more embedded sensors 218. Each embedded sensor 218 may be placed on a circuit-under-test 216. The circuit-under-test 216 may be a portion of the integrated circuit 106 on the DUT 104. Each embedded sensor 218 may receive controlling instructions via the digital bus 220. For example, the digital bus 220 may put each embedded sensor 218 into a specific state. Each embedded sensor 218 may include one or more switches. Each switch may determine the connection between the embedded sensor 218 and the circuit-under-test 216. For example, a switch in the ‘on’ position may indicate that a particular node on the circuit-under-test 216 is to be probed with a particular voltage. As another example, a switch in the ‘on’ position may indicate that a measurement is to be taken of a particular node in the circuit-under-test 216.

The register 222 may send instructions to the embedded sensors 218 through the digital bus 220. For example, the register 222 may instruct each embedded sensor 218 to turn certain switches to ‘on’ and ‘off’ positions. The register 222 may send digital instructions to each embedded sensor 218 according to the specific tests performed on the circuit-under-test 216.

The register 222 may also communicate with the embedded sensors 218 through an analog bus 214. The analog bus 214 may be a standard feature on the DUT 104.

The BiST system 210 may include a controller 212. The controller 212 may control the BiST system 210. For example, the controller 212 may be a central controller for the BiST system 210. A single controller 212 may be used to control multiple embedded sensors 218 on multiple circuits-under-test 216. The controller 212 may be used to control the register 222. The controller 212 may receive instructions from the ATE 202 via the SBI_IN 226, the bus interface 224 and the digital bus 220. For example, the controller 212 may receive instructions concerning which tests are to be performed on a circuit-under-test 216. The controller 212 may also receive instructions identifying the circuit-under-test 216. For example, the controller 212 may receive the address of the circuit-under-test 216. The controller 212 may also be used to control each of the embedded sensors 218. The controller 212 may communicate with the embedded sensors 218 through an analog bus 214. An analog bus 214 is typically used in analog and mixed signal protocols. The controller 212 may generate probe signals for the circuit-under-test 216 and send these probe signals to the circuit-under-test 216 via the embedded sensors 218 and the analog bus 214.

The controller 212 may also receive signal responses from the embedded sensors 218 via the analog bus 214. The received signal responses may be analog measurements made on the circuit-under-test 216. For example, the received signal response may include DC measurements taken by the embedded sensors 218 from the circuit-under-test 216. The controller 212 may perform operations on the received signal responses. For example, the controller 212 may convert the received signal responses from analog measurements to digital measurements. The controller 212 may provide the received signal responses to the ATE 202 via the digital bus 220, the bus interface 224 and SBI_OUT 228.

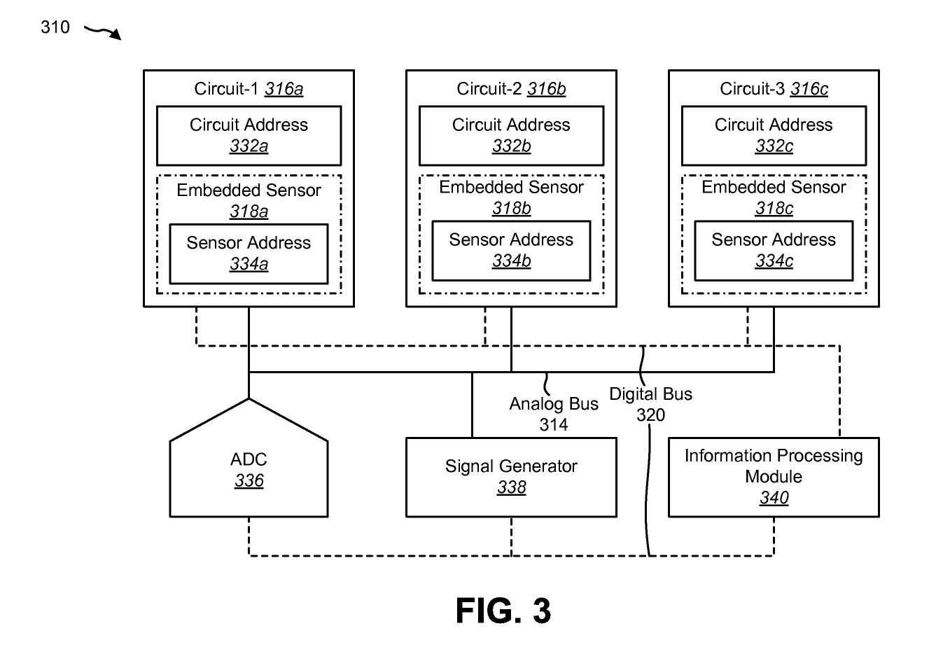

FIG. 3 is a block diagram illustrating a BiST system 310 for use in the present systems and methods. The BiST system 310 may include multiple integrated circuits 316a-c. Each integrated circuit 316 may have a circuit address 332a-c associated with the integrated circuit 316. The circuit addresses 332 may assist the BiST system 310 in differentiating between each integrated circuit 316a-c.

Each integrated circuit 316 may include one or more embedded sensors 318a-c. The embedded sensors 318 may interact with the integrated circuits 316. For example, the embedded sensors 318 may provide access to nodes within the integrated circuits 316. The embedded sensors 318 may allow an integrated circuit 316 to be probed and measurements to be taken of internal nodes within the integrated circuit 316. Each of the embedded sensors 318 may have a sensor address 334a-c associated with the embedded sensor 318. A sensor address 334 may assist the BiST system 310 in differentiating between each embedded sensor 318.

Each embedded sensor 318 may have one or more switches. Each switch may allow an embedded sensor 318 to communicate with an integrated circuit 316 at a different node. For example, when a first switch within an embedded sensor 318 is switched to the ‘on’ position, the embedded sensor 318 may probe the integrated circuit 316 at the integrated circuit node attached to the first switch. As another example, when a second switch within the embedded sensor 318 is switched to the ‘on’ position, the embedded sensor 318 may make measurements at the integrated circuit node attached to the second switch.

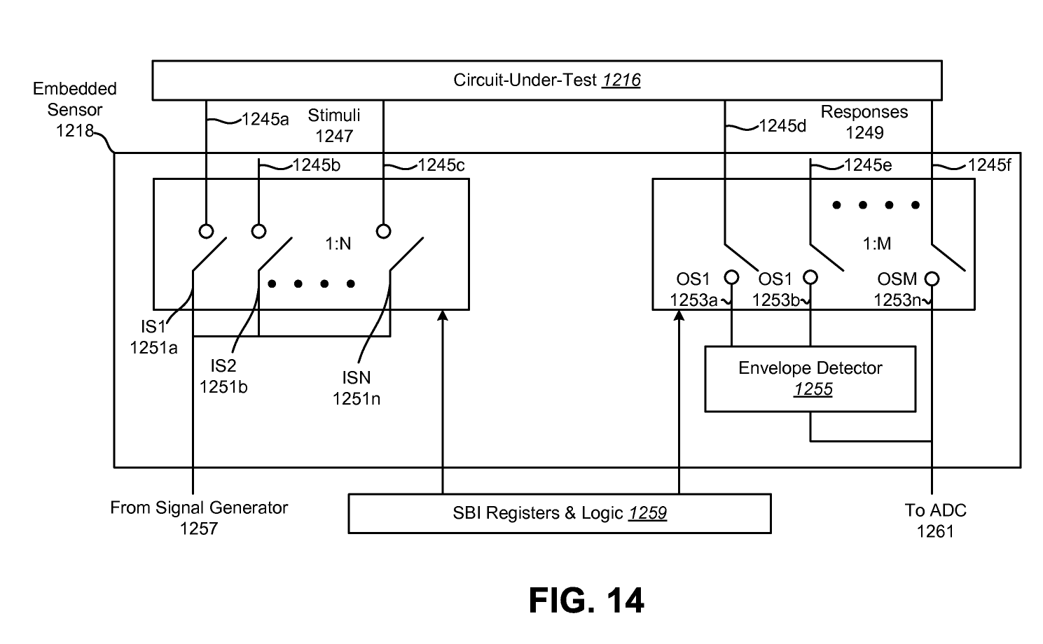

An embedded sensor 318 may receive instructions over a digital bus 320. The instructions may indicate which switches on the embedded sensor 318 are to be turned ‘on’ or ‘off.’ The switches on an embedded sensor 318 are discussed in more detail below in relation to FIGS. 14-16. An embedded sensor 318 may convert DC/RF measurements taken on an integrated circuit 316 to equivalent DC levels. In one configuration, an embedded sensor 318 may convert DC/RF measurements taken on an integrated circuit 316 to equivalent DC levels using an envelope detector. Envelope detectors are discussed in more detail below in relation to FIG. 14.

The BiST system 310 may include a signal generator 338. The signal generator 338 may use an existing frequency synthesizer on the DUT 104. Thus, the signal generator 338 may generate signals on-die. The signal generator 338 may generate mixed signals for testing the integrated circuits 316. The generated mixed signals may perturb an integrated circuit 316 through an embedded sensor 318. The signal generator 338 may send the generated mixed signals to an embedded sensor 318 via an analog bus 314.

The BiST system 310 may include an analog-to-digital convertor (ADC) 336. The ADC 336 may be located on the DUT 104. For example, the ADC 336 may be a housekeeping ADC required on SoCs. The ADC 336 may receive measurements taken by the embedded sensors 318. The ADC 336 may receive these measurements after the measurements have been converted to equivalent DC levels using an envelope detector. Alternatively, the ADC 336 may receive the measurements directly without conversion. The ADC 336 may receive measurements taken by the embedded sensors 318 via the analog bus 314.

The BiST system 310 may include an information processing module 340. The information processing module 340 may be a finite state machine (FSM). The information processing module 340 may be located on the DUT 104. For example, the information processing module 340 may be embedded within the controller 212 of the BiST system 310. Alternatively, the information processing module 340 may be located externally. For example, the information processing module 340 may be located on an ATE 202.

The information processing module 340 may receive the measurements from the ADC 336. Because the ADC 336 has converted the measurements from analog to digital, the information processing module 340 may receive the measurements from the ADC 336 via the digital bus 320. The information processing module 340 may also communicate with the signal generator 338. For example, the information processing module 340 may set the signal generator 338 outputs to specific frequencies or adjust the amplitudes of the signals generated by the signal generator 338. The information processing module 340 may provide a digital interface for analog testing.

The information processing module 340 may use an existing Advanced RISC (reduced instruction set computing) Machine (ARM)/Joint Test Action Group (JTAG) core. JTAG refers to the Institute of Electrical and Electronics Engineers (IEEE) 1149.1 standard entitled Standard Test Access Port and Boundary-Scan Architecture. In the absence of an on-chip information processing module 340, an external tester with an appropriately configured software routine may be used with similar functionality as the information processing module 340.

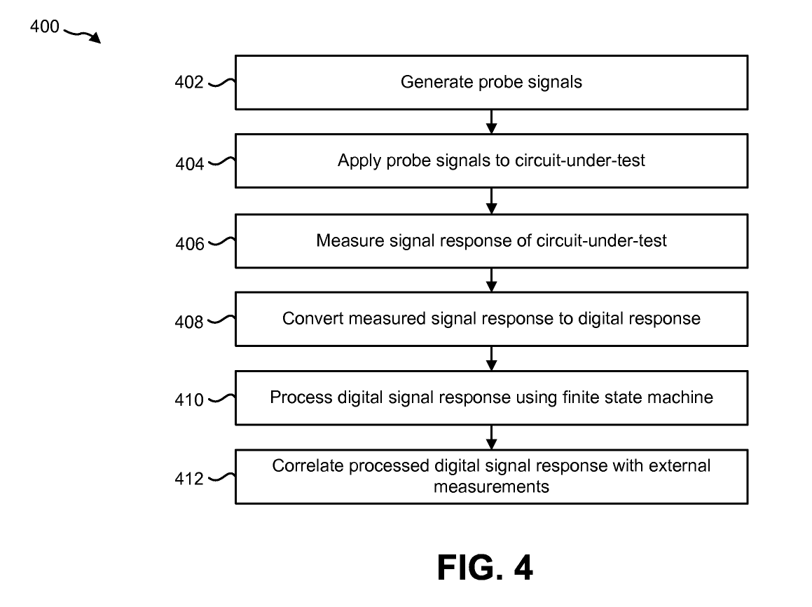

FIG. 4 is a flow diagram illustrating a method 400 for providing a built-in self test (BiST) of mixed signal integrated circuits 316. A BiST system 310 may be located on a DUT 104. The BiST system 310 may provide testing of mixed signal integrated circuits 316 according to a testing procedure. The testing procedure may be defined by a user of the BiST system 310. A signal generator 338 may generate 402 probe signals. The probe signals may be generated according to the testing procedure. An embedded sensor 318 may apply 404 the probe signals to a circuit-under-test. The embedded sensor 318 may apply 404 the probe signals to the circuit-under-test using a switch in the embedded sensor. The circuit-under-test may be an integrated circuit 316. The circuit-under-test may be a mixed-signal circuit. The embedded sensor 318 may then measure 406 the signal response of the circuit-under-test.

An ADC 336 may convert 408 the measured signal response to a digital signal response. An FSM 340 may process 410 the digital signal response. The FSM 340 may then correlate 412 the processed digital signal response with external measurements. For example, the external measurements may be a relatively small number of off-chip measurements with a high level of accuracy. The off-chip measurements may be performed by an analog ATE 102. In contrast, the processed digital signal response of the measurements taken by the BiST system 310 represents a relatively large number of on-chip measurements with a lower level of accuracy. Using a statistical correlation, it can be determined whether the particular integrated circuit 316 passes or fails a certain figure of merit. Thus, it may be determined whether the DUT 104 can be shipped to customers.

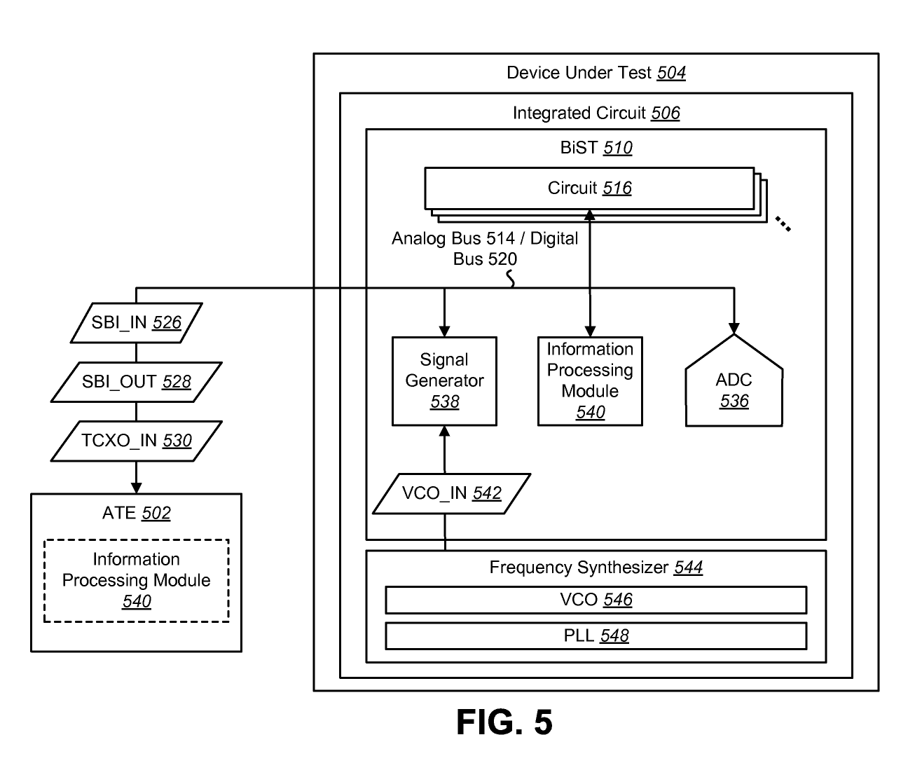

FIG. 5 is a block diagram illustrating one configuration of a signal generator 538 in a BiST system 510. In particular, FIG. 5 illustrates an on-chip signal generation system for a BiST system 510. A device under test (DUT) 504 may be a cellular phone, a personal digital assistant (PDA), a smart phone, an e-reader, a laptop computer, or a wireless modem, for example. The DUT 504 may include an integrated circuit 506. The integrated circuit 506 may include a BiST system 510 and a frequency synthesizer 544. One example of the frequency synthesizer 544 is an RF synthesizer 544 used to produce an RF signal for use by the DUT 504. The frequency synthesizer 544 may include a Voltage Controlled Oscillator (VCO) 546 and a Phase-Locked-Loop (PLL) 548. The frequency synthesizer 544 may use the VCO 546 and the PLL 548 to generate a signal at a given frequency. For example, the frequency synthesizer 544 may produce a signal used by the DUT 504 to produce a wireless transmission signal. That is, the frequency synthesizer 544 may be designed to be used primarily for integrated circuit 506 functions other than those of the BiST 510. In one configuration, the frequency synthesizer 544 may be used for BiST 510 functions during testing, but may then be used to perform other functions on the integrated circuit 506. Additionally, the BiST 510 may be disabled after testing but before shipping to a customer or consumer.

The BiST system 510 may be BiST circuitry that may include one or more circuits 516 for testing, a signal generator 538, an information processing module 540 and an Analog-to-Digital Converter (ADC) 536. As described above, the information processing module 540 may be alternatively included in external Automated Testing Equipment (ATE) 502. The ADC 536 may be used to convert analog signals (e.g., analog signals output from the one or more circuits 516) to digital signals for transmission to the ATE 502 as discussed above. The BiST system 510 may also include an analog bus 514 and a digital bus 520. For simplicity, the analog bus 514 and digital bus 520 are illustrated as a single bus 514, 520 in FIG. 5. The ATE 502 may be connected to the digital bus 520. The digital bus 520 may be used by the ATE 502 to send SBI_IN signals 526 and receive SBI_OUT signals 528. The BiST system 510 may test one or more circuits 516 as described above. As referred to herein, a “BiST system” may generally comprise BiST circuitry.

The frequency synthesizer 544 may generate a signal 542 at a particular frequency to be input into the signal generator 538. In one configuration, the frequency synthesizer 544 generates a “VCO_IN” signal 542 that is input into the signal generator 538. The VCO_IN signal 542 may be a sinusoidal signal. The VCO_IN signal 542 may comprise differential signals. For example, two signals may be sent on separate conductors to the signal generator 538. The second signal may be an inverted version of the first signal. In one configuration, the first signal may be deemed VCO_IN (e.g., V⁺), while the second signal is deemed VCO_IN⁻ (e.g., V⁻). When a differential signal is referred to herein, the positive signal is generally referred to without a plus superscript (e.g., VCO_IN⁺ may be referred to as VCO_IN), while the negative signal is denoted with a minus superscript (e.g., VCO_IN⁻). Furthermore, a combination of both positive and negative differential signals may be generally referred to as a signal without a superscript (e.g., VCO_IN) depending on context. Thus, VCO_IN 542 may comprise positive and negative differential signals when referred to generally or VCO_IN may refer to a single positive differential signal when used in a specific context. The Automated Testing Equipment (ATE) 502 may also generate a digital reference clock signal 530 (e.g., square wave) at another particular frequency to be input into the signal generator 538. The digital reference clock signal may be distributed as a stimulus using the analog bus 514. In one configuration, this reference clock signal is deemed “TCXO_IN” 530. Because the signal generator 538 uses the “existing” frequency synthesizer 544 (e.g., to be used for the principal functionality of the DUT 504) and the external reference clock (e.g., TCXO_IN 530), it 538 may require relatively low integrated circuit 506 area overhead for implementation. The signal generator 538 may use the external reference clock signal 530 and the on-chip frequency synthesizer 544 signal 542 to generate test signals used by the BiST system 510. The signal generator 538 may be connected to a distributed network of embedded sensors (e.g., for measuring signals at certain nodes in the circuits 516). The signals generated by the signal generator 538 may be transmitted on a narrow analog bus 514 that is dedicated for the BiST 510. Signal generation will be described in greater detail below.

The information processing module 540 may determine which signals are generated by the signal generator 538. For example, the information processing module 540 may send control signals to the signal generator 538 that determine how the external reference clock signal (e.g. TCXO_IN) 530 and frequency synthesizer 544 signal (e.g., VCO_IN) 542 are utilized to generate one or more desired test signals. In other words, the information processing module 540 (e.g., finite state machine) may control the signal generator's 538 amplitude and frequency. The control signals may be sent to the signal generator 538 using the digital bus 520. The information processing module 540 control of the signal generator 538 may be specified by a user or an ATE 502, for example.

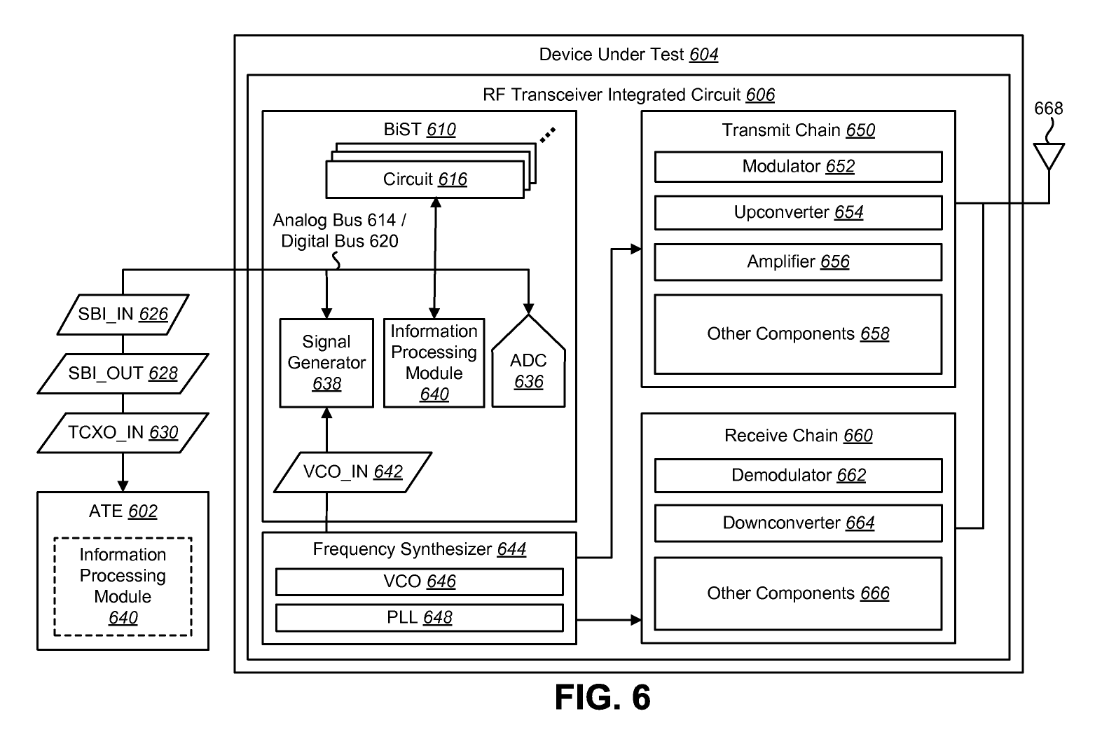

FIG. 6 is a block diagram illustrating a more specific example of a device under test (DUT) 604. In this example, the DUT 604 includes an RF transceiver integrated circuit 606. The RF transceiver integrated circuit 606 includes a BiST 610 system, a frequency synthesizer 644, a transmit chain 650 and a receive chain 660. The RF transceiver integrated circuit 606 may also be coupled to one or more antennas 668. Wireless communication signals (e.g., for transmission) may be generated by the RF transceiver integrated circuit 606. The RF transceiver integrated circuit 606 may also be used to receive wireless communication signals. For example, a cellular phone may include the RF transceiver integrated circuit 606 and may use it 606 to communicate with a base station.

The BiST 610 may be configured similarly to the BiST 510 discussed above in connection with FIG. 5. For example, the BiST 610 may include one or more circuits for testing 616, an analog bus 614, a digital bus 620, a signal generator 638, an ADC 636 and an optional information processing module 640. While undergoing testing, an ATE 602 may be connected to the digital bus 620. The ATE 602 may send a TCXO_IN (i.e., reference clock) signal 630 to the BiST 610. SBI_IN 626 and SBI_OUT 628 signals may be used by the ATE 602 to communicate with the BiST 610. As mentioned above, the information processing module 640 may be optionally included in the ATE 602 or the BiST 610.

The frequency synthesizer 644 may include a VCO 646 and a PLL 648. Similar to the configuration discussed in connection with FIG. 5 above, the frequency synthesizer 644 may generate a VCO_IN 642 signal to be used by the signal generator 638. However, the frequency synthesizer 644 may be primarily used to drive one or more components included in the transmit chain 650 and in the receive chain 660. The transmit chain 650 may include components used to generate a signal for transmission. In this example, the transmit chain 650 includes a modulator 652, an upconverter 654, an amplifier 656 and other components 658. The components included in the transmit chain 650 may generally format a data or voice signal for transmission. In contrast, the receive chain 660 may include components used to receive a signal. In this example, the receive chain 660 includes a demodulator 662, a downconverter 664 and other components 666. One or more components included in the transmit chain 650 and/or the receive chain 660 may use one or more signals generated by the frequency synthesizer 644. In one configuration, the frequency synthesizer 644 is included on the same RF transceiver integrated circuit 606 as components in the transmit chain 650 and components in the receive chain 660. Furthermore, the circuits 616 included in BiST 610 may comprise one or more components 652, 654, 656, 658, 662, 664, 666 (e.g., or subcomponents) included in the transmit chain 650 and/or the receive chain 660. Thus, the BiST 610 may test one or more of these components using a frequency synthesizer 644 included on the same RF transceiver integrated circuit 606 as well as an ATE 602 that provides an external reference clock signal (e.g., TCXO_IN) 630. It should also be noted, however that other modules, components, subcomponents or circuits (e.g., any that are accessible by the BiST 610) not included in the transmit chain 650 or receive chain 660 may be tested by the BiST 610 system.

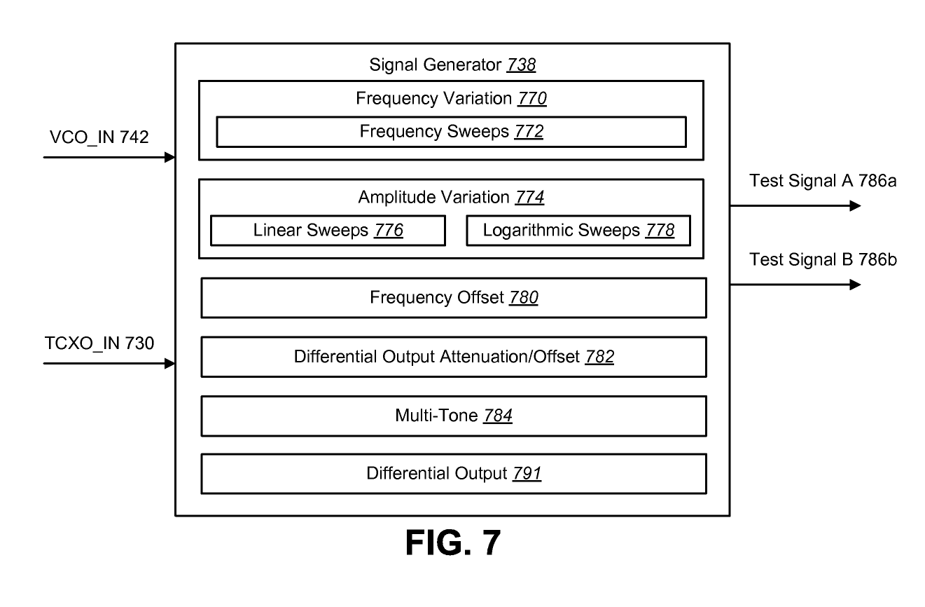

FIG. 7 is a block diagram illustrating possible functionality in one configuration of a signal generator 738. The signal generator 738 may be designed to generate a variety of test signals 786a-b using a signal 742 from a local oscillator (e.g., a frequency synthesizer 544 on the same integrated circuit 506 as the signal generator 738) and a signal 730 from an external source. For example, the signal generator 738 may receive a signal (e.g., “VCO_IN”) 742 from a local frequency synthesizer 544 and another signal (e.g., “TCXO_IN”) 730 from an external source (e.g., ATE 102). The VCO_IN signal 742 may be at a different frequency than the TCXO_IN signal 730. For example, the VCO_IN signal 742 may be at a higher frequency than the TCXO_IN signal 730. The generated test signals 786a-b may be used to test (e.g., generate a measured output for) one or more circuits under test 216.

The signal generator 738 may generate test signals 786a-b at varying (e.g., interpolated) frequencies using frequency variation 770 functionality. For example, assuming that the DUT 104 uses a wireless transceiver, the signal generator 738 may generate signals at output frequencies in the operating range of the transceiver. The frequency variation 770 functionality may be used to generate one or more frequency sweeps 772 in the one or more test signals 786a-b. More specifically, a frequency sweep 772 may vary the frequency of the one or more test signals 786a-b across a range of frequencies. Interpolated frequencies that may be used for frequency sweeps 772 may be generated by mixing the on-chip VCO_IN 742 signal and the off-chip reference (e.g., TCXO_IN) 730. The VCO_IN 742 signal and/or the TCXO_IN 730 signal may be divided. For example, a divided VCO_IN 742 signal may be mixed with a divided TCXO_IN 730 signal to provide interpolated frequencies used in a frequency sweep 772.

The signal generator 738 may be configured to provide amplitude variation 774 in one or more test signals 786a-b. For example, the amplitude variation 774 functionality allows the signal generator 738 to output test signals 786a-b at varying amplitudes. Specifically, amplitude control to conduct linear sweeps 776 and logarithmic sweeps 778 may be provided by the amplitude variation 774 functionality. A linear sweep 776 in test signal amplitude 786a-b may vary the amplitude of one or more test signals 786a-b linearly across a range of amplitudes. A logarithmic sweep 778, however, may vary the amplitude of one or more test signals 786a-b logarithmically across a range of amplitudes. The amplitude variation 774 functionality may be used to measure compression and/or linearity characteristics of a circuit under test 216.

The signal generator 738 may output test signal 786a-b outputs that are offset from the local oscillator signal (VCO_IN) 742 frequency using frequency offset 780 functionality. These frequency-offset test signals 786 may be generated in either the Upper Sideband (USB) or Lower Sideband (LSB). The test signal 786a-b outputs that are offset to the VCO_IN 742 frequency may be used to conduct down-conversion measurements, for example. For instance, conversion gain is one type of measurement that can be performed using down-conversion. Furthermore, other parameters such as amplitude error between differential signals after down-conversion could be measured. The signal generator 738 may also provide differential output test signals 786a-b using differential output 791 functionality.

Other test signal 786a-b output functionality may be included in the signal generator 738 that may enable certain kinds of measurements on one or more circuits under test 216. For example, the signal generator 738 may provide differential output attenuation/offset functionality 782. That is, the signal generator 738 may add attenuation/offset to each test signal 786a-b in a differential output. The differential output attenuation/offset 782 functionality may allow measurement of imbalances in circuits under test 216 that are correlated to second-order intermodulation product (IM2). Multi-tone 784 functionality may be used to produce multiple (e.g. two) frequency tones that are output on the test signals 786a-b. For example, the multi-tone 784 functionality may allow the generation of a Double Sideband-Suppressed Carrier (DSB-SC) signal. In this way, the signal generator 738 may provide multi-tone 784 (e.g., two-tone) test signals 786a-b for third-order input intercept point (IIP3) measurements. In one configuration, the signal generator 738 may generate multiple tones (e.g., more than two tones) for use in testing.

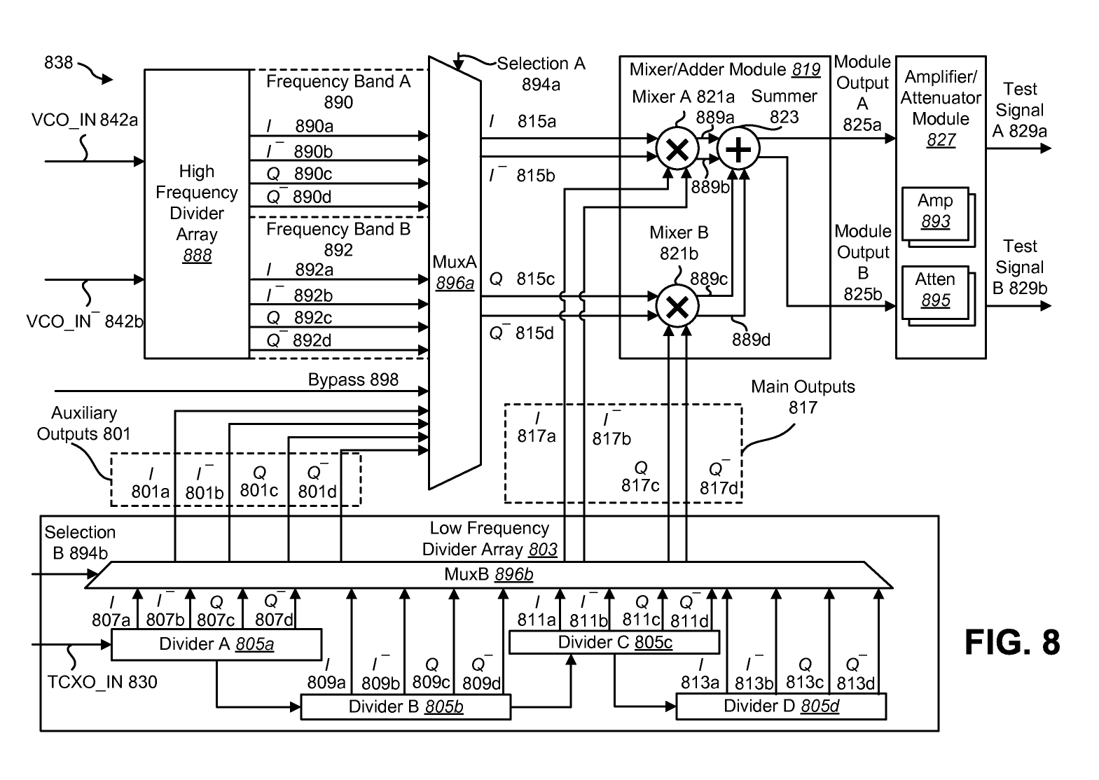

FIG. 8 is a block diagram illustrating one specific configuration of a signal generator 838. The signal generator 838 may include a high frequency divider array 888, a low frequency divider array 803, multiplexer (mux) A 896a, a mixer/adder module 819 and an amplifier/attenuator module 827. The signal generator 838 may receive differential signals VCO_IN 842a and VCO_IN⁻ 842b from a local oscillator (e.g., frequency synthesizer 544). For example, VCO_IN⁻ 842b may be an inverted version (e.g., in voltage) of VCO_IN 842a. The differential VCO_IN 842a and VCO_IN⁻ 842b signals may be input into the high frequency divider array 888.

The high frequency divider array 888 may include one or more frequency dividers and other components (not shown). The other components mentioned may include, for example, buffer amplifiers embedded in the frequency dividers for high frequency operation. Frequency dividers that use these buffer amplifiers may be characterized simply as “high frequency dividers.” A first frequency divider (not shown) included in the high frequency divider array 888 may divide the frequency of an incoming signal (e.g., VCO_IN 842a, VCO_IN⁻ 842b) by a factor of two. For example, if the incoming signal is a 2 gigahertz (GHz) signal, the first frequency divider would output a 1 GHz signal. A subsequent frequency divider may further divide the frequency of the signal. In continuing the example, a second divider may divide the 1 GHz signal into a 500 megahertz (MHz) signal. Thus, several frequency dividers in series may yield increasing divisions on an input signal. For example, a frequency divider output signal may be at ½ of the original frequency after the first frequency divider, at ¼^{th} after the second, at ⅛^{th} after the third and so on. The other components included in the high frequency divider array 888 may ensure a correct signal amplitude and low phase noise to maintain signal quality. The high frequency divider array 888 may generate differential in-phase (I, I⁻) and differential quadrature (Q, Q⁻) signals (i.e., collectively referred to as differential quadrature signals (I, I⁻, Q, Q⁻) depending on context) by using frequency division. For example, I⁻ is an inverted version of I, and Q⁻ is an inverted version of Q. Thus, on-chip frequency synthesizer 544 output signals (e.g., VCO_IN 842a, VCO_IN⁻ 842b) may be “reused” to generate quadrature signals using the high frequency divider array 888.

The high frequency divider array 888 may generate differential in-phase and quadrature signals in one or more frequency bands. For example, I 890a, I⁻ 890b, Q 890c and Q⁻ 890d may be generated by the high frequency divider array 888 in frequency band A 890. Additionally, I 892a, I⁻ 892b, Q 892c and Q⁻ 892d may be generated by the high frequency divider array 888 in frequency band B 892. In one configuration, frequency band A 890 is the L-band and frequency band B 892 is the Ultra High Frequency (UHF) band. Differential in-phase and quadrature signals may be generated in additional frequency bands. The high frequency divider array 888 may generally generate output signals based on the local oscillator signals 842a-b. It should be noted that the term “differential quadrature signals” or simply “quadrature signals” may include both in-phase (e.g., I, I⁻) and quadrature (e.g., Q, Q⁻) signals when used in a general context.

The low frequency divider array 803 may include several dividers 805a-d and multiplexer (mux) B 896b. An external reference clock signal (e.g., TCXO_IN) 830 may be received by the low frequency divider array 803 and input into frequency divider A 805a. Each of the frequency dividers 805a-d included in the low frequency divider array 803 may divide the frequency of an input signal by a factor of 2. Thus, the frequency of the output of each divider may be half of the frequency of the input signal. More specifically, the frequency of the output of divider A 805a may be at ½ that of TCXO_IN 830, the output frequency of divider B 805b may be at ¼^{th} that of TCXO_IN 830, the output frequency of divider C 805c may be ⅛^{th} that of TCXO_IN 830 and the output frequency of divider D 805d may be 1/16^{th} that of TCXO_IN 830. Optionally, the low frequency divider array may output differential quadrature signals (I, I⁻, Q, Q⁻) at the same frequency as TCXO_IN 830. Thus, the low frequency divider array 803 may generally output signals based on the TCXO_IN 830 signal.

Each divider 805a-d may output differential in-phase and differential quadrature signals (I, I⁻, Q, Q⁻). More specifically, divider A 805a may output I 807a, I⁻ 807b, Q 807c and Q⁻ 807d at one frequency (e.g., ½ of TCXO_IN 830), divider B 805b may output I 809a, I⁻ 809b, Q 809c and Q⁻ 809d at another frequency (e.g., ¼^{th} of TCXO_IN 830), divider C 805c may output I 811a, I⁻ 811b, Q 811c and Q⁻ 811d at another frequency (e.g., ⅛^{th} of TCXO_IN 830) and divider D 805d may output I 813a, I⁻ 813b, Q 813c and Q⁻ 813d at yet another frequency (e.g., 1/16^{th} of TCXO_IN 830). Thus, an external reference clock signal (e.g., TCXO_IN 830) may be “reused” by the low frequency divider array 803 to generate low-frequency quadrature signals with specific division ratios.

These differential in-phase and differential quadrature signals may be input into multiplexer B 896b. Multiplexer B 896b may include two sets of outputs: main outputs 817 and auxiliary outputs 801. Multiplexer B 896b may also receive and utilize selection signal B 894b. For example, an information processing module 340 may generate and send selection signal B to the low frequency divider array 803. Selection signal B 894b may select differential in-phase and/or differential quadrature signals (I, I⁻, Q, Q⁻) from the dividers 805a-d to be output as main outputs 817a-d and/or auxiliary outputs 801. For example, both the main outputs 817 and the auxiliary outputs 801 may be from the same divider 805 (i.e., in the same frequency band). Alternatively, the main outputs 817 may be from one divider 805 (i.e., in a first frequency band) while the auxiliary outputs 801 may be from another divider (i.e., in a second frequency band). In one example, selection signal B 894b selects divider A's 805a outputs I 807a, I⁻ 807b, Q 807c and Q⁻ 807d to be output from multiplexer B 896b as auxiliary outputs I 801a, I⁻ 801b, Q 801c and Q⁻ 801d, respectively. Continuing with the example, selection signal B 894b may select divider D's 805d outputs (I, I⁻, Q, Q⁻) 813a-d to be multiplexer B's 896b main outputs (I, I⁻, Q, Q⁻) 817a-d.

Multiplexer A 896a may receive the auxiliary outputs 801. Selection signal A 894a (e.g., which may be generated by and received from an information processing module 340) may select the multiplexer A 896a outputs 815a-d. For example, multiplexer A 896a may select a complete differential quadrature set (I, I⁻, Q, Q⁻) from one of the frequency bands (e.g., 890, 892, 801). Multiplexer A 896a may also select a different frequency set if it is applied separately to multiplexer A 896a. Each of multiplexer A's 896a outputs 815a-d may be selected from the quadrature signals (I, I⁻, Q, Q⁻) from one of the frequency bands 890, 892 generated by the high frequency divider array 888 or the selected frequency band from the auxiliary outputs 801 from the low frequency divider array 803. For example, multiplexer A 896a may use selection signal A 894a to select signals from frequency band B 892. For instance, frequency band B's 892 outputs (I, I⁻, Q, Q⁻) 892a-d may be may selected to be multiplexer A's outputs (I, I⁻, Q, Q⁻) 815a-d. A bypass signal 898 may also be input into multiplexer A 896a. The bypass signal 898 may be manually connected to an external pin (e.g., on the DUT 104). The bypass signal 898 may be used for debugging (e.g., to input an external signal of known amplitude and frequency).

The selected outputs 815a-d from multiplexer A 896a and the main outputs 817a-d from the low frequency divider array 803 (i.e., a combination of quadrature signals) may be fed to a mixer/adder module 819. The mixer/adder module 819 may use mixers 821 and/or a summer (e.g., adder) 823 to generate upper sideband (USB), lower sideband (LSB), double sideband (DSB) or double sideband suppressed carrier (DSB-SC) module output signals 825a-b, depending on the multiplexer 896a-b outputs 815, 817. In the configuration illustrated in FIG. 8, the mixer/adder module 819 includes two mixers 821a-b and one summer 823. One example of a mixer 821 is a Gilbert cell mixer. Mixer A 821a may mix the in-phase outputs (I, I⁻) 815a-b from multiplexer A 896a with the in-phase outputs (I, I⁻) 817a-b from multiplexer B 896b. Mixer B 821b may mix the quadrature outputs (Q, Q⁻) 815c-d from multiplexer A 896a with the quadrature outputs (Q, Q⁻) 817c-d from multiplexer B 896b. The mixed signal outputs 889a-b from mixer A 821a and the mixed signal outputs 889c-d from mixer B 821b may optionally be summed by the summer 823. For example, if USB or LSB outputs are desired, then the summer 823 may sum the mixed signal outputs 889a-d. However, if a DSB output is desired, the mixed signal outputs 889a-d may not be summed. This will be described in greater detail below. The mixer/adder module 819 generates mixer/adder module outputs A and B 825a-b. The mixer/adder module output A 825a and mixer/adder module output B 825b may be differential signals. Summing (e.g., addition of) 823 in-phase (I) and quadrature (Q) currents may result in upper sideband (USB) or lower sideband (LSB) signals at the mixer/adder module outputs 825a-b. However, to generate a double sideband (DSB) signal, the mixed signal outputs 889a-d may not be summed. The upper sideband, lower sideband and/or double sideband signals may be used for conversion gain and third-order input intermodulation (IIP3) measurements of one or more circuits under test 216.

The mixer/adder module 819 outputs 825a-b may be input into the amplifier/attenuator module 827. The amplifier/attenuator module 827 may amplify and/or attenuate the mixer/adder module 819 output signals 825a-b to generate test signal A 829a and test signal B 829b. The amplifier/attenuator module 827 may provide attenuation and/or amplification to the test signals 829a-b for linear and logarithmic sweeps. More specifically, one or more programmable amplifiers 893 (abbreviated as “Amp” for convenience in FIG. 8) and/or attenuators 895 (abbreviated as “Atten” for convenience in FIG. 8) included in the amplifier/attenuator module 827 may allow this logarithmic or linear variation of test signal 829a-b amplitudes. Additionally, gain offsets in differential outputs (e.g., halves) 829a-b may be provided by the amplifier/attenuator module for second-order intermodulation (IM2)-type testing or measurements.

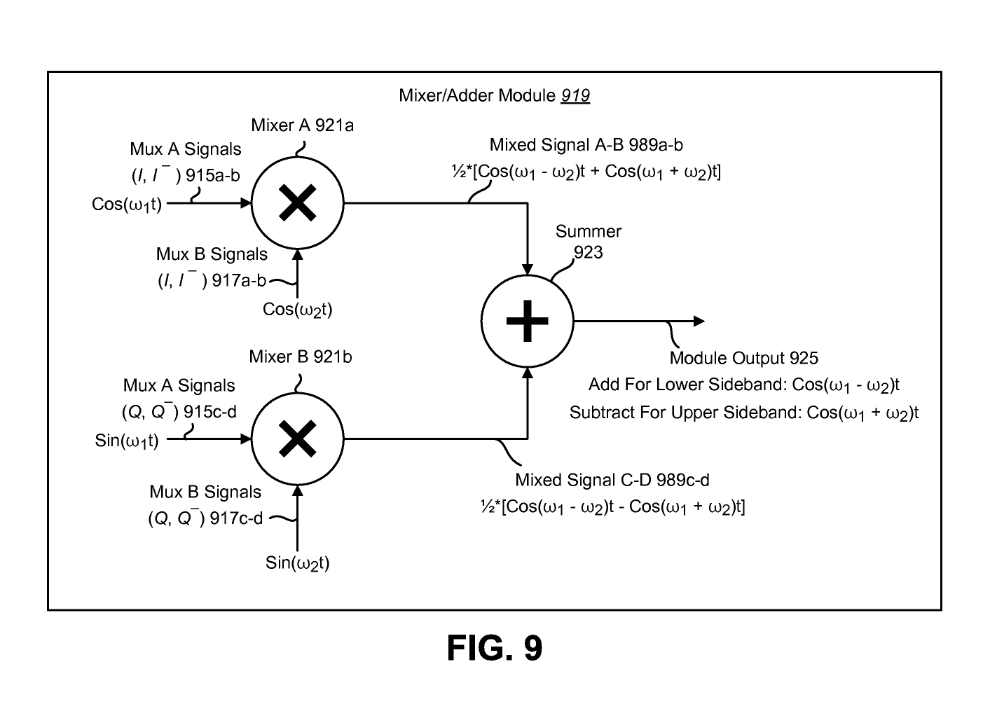

FIG. 9 is a block diagram illustrating more detail of one configuration of a mixer/adder module 919. As described above, the mixer/adder module 919 may include two mixers 921a-b and a summer 923. Mixer A 921a receives and mixes multiplexer A 896a in-phase (I, I⁻) signals 915a-b (e.g., Cos(ω₁t), where ω represents frequency and t represents time herein) with multiplexer B 896b in-phase signals (I, I⁻) 917a-b (e.g., Cos(ω₂t)) to generate mixed signal(s) A-B 989a-b (e.g., ½*[Cos(ω₁−ω₂)t+Cos(ω₁+ω₂)t]). Mixer B 921b receives and mixes multiplexer A 896a quadrature signals (Q, Q⁻) 915c-d (e.g., Sin(ω₁t)) with multiplexer B 896b quadrature signals (Q, Q⁻) 917c-d (e.g., Sin(ω₂t)) to generate mixed signal(s) C-D 989c-d (e.g., ½*[Cos(ω₁−ω₂)t−Cos(ω₁+ω₂)t]). The summer 923 may add or subtract mixed signals A-B 989a-b and mixed signals C-D 989c-d to generate a mixer/adder module 919 output 925. Alternatively, the mixed signals A-D 989a-d may not be added in order to generate a double sideband (DSB) signal at the module output 925. Adding the mixed signals A-B 989a-b to the mixed signals C-D 989c-d may produce a lower sideband (LSB) signal (e.g., Cos(ω₁−ω₂)t) at the mixer/adder module 919 output 925. Subtracting the mixed signals A-D 989a-d may produce an upper sideband (USB) signal (e.g., Cos(ω₁+ω₂)t) at the mixer/adder module 919 output 925.

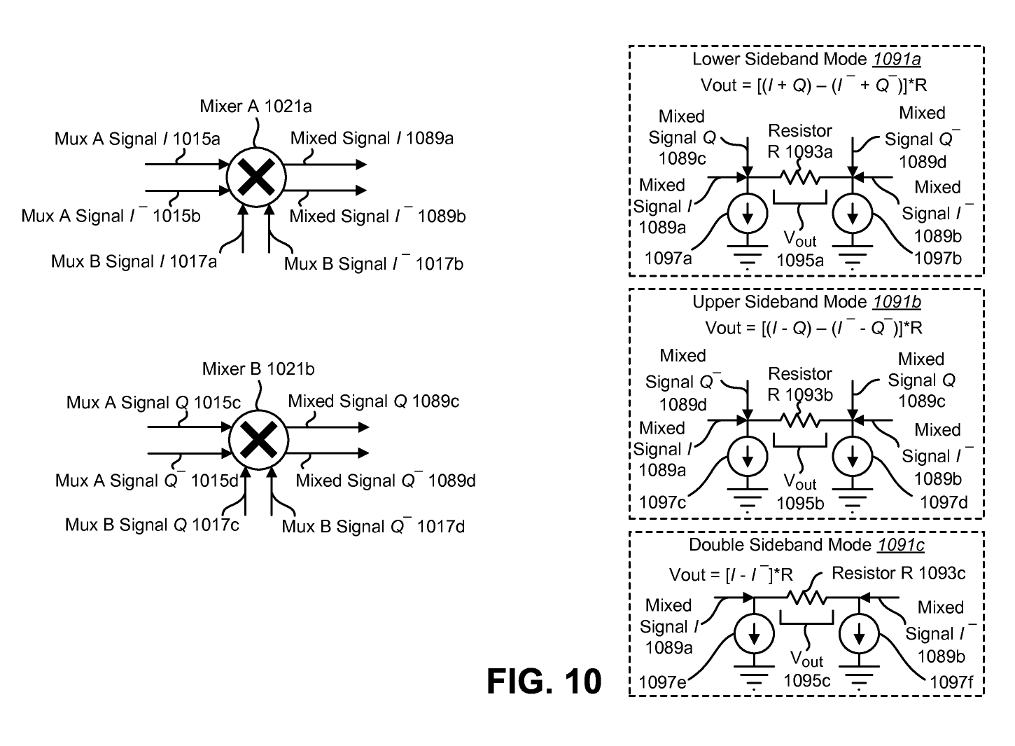

FIG. 10 is a block diagram illustrating more detail of the functionality of one configuration of a mixer/adder module 819. Mixer A 1021a receives and mixes multiplexer A 896a in-phase signals (I, I⁻) 1015a-b with multiplexer B 896b in-phase signals (I, I⁻) 1017a-b to generate mixed in-phase (I, I⁻) signals 1089a-b. Mixer B 1021b receives and mixes multiplexer A 896a quadrature signals (Q, Q⁻) 1015c-d with multiplexer B 896b quadrature signals (Q, Q⁻) 1017c-d to generate mixed quadrature signals (Q, Q⁻) signals 1089c-d.

The mixer/adder module 819 may include three modes. A lower sideband (LSB) mode 1091a may be used to generate a lower sideband (LSB) signal. An upper sideband (USB) mode 1091b may be used to generate an upper sideband (USB) signal. Finally, a double sideband (DSB) mode 1091c may be used to generate a double sideband (DSB) signal.

Mixed signals 1089a-d (e.g., currents) may (or may not) be combined or summed in different ways to produce a desired type of signal. For example, the LSB mode 1091a may use a resistor R 1093a and current sources 1097a-b along with mixed signals 1089a-d to produce a voltage output signal 1095a. In this example, a mixed signal Q 1089c is combined with a mixed signal I 1089a and a mixed signal Q⁻ 1089d is combined with a mixed signal I⁻ 1089b across a resistor R 1093a to produce an LSB voltage output (Vₒᵤₜ) 1095a signal. The voltage output 1095a in LSB mode 1091a may be expressed as Vₒᵤₜ=[(I+Q)−(I⁻+Q⁻)]*R.

In another example, the upper sideband (USB) mode 1091b may use a resistor R 1093b and current sources 1097c-d along with mixed signals 1089a-d to produce a voltage output signal 1095b. In this example, a mixed signal Q⁻ 1089d is combined with a mixed signal I 1089a and a mixed signal Q 1089c is combined with a mixed signal I⁻ 1089b across a resistor R 1093b to produce a USB voltage output (Vₒᵤₜ) 1095b signal. The voltage output 1095b in USB mode 1091b may be expressed as Vₒᵤₜ=[(I−Q)−(I⁻−Q⁻)]*R.

In yet another example, the double sideband (DSB) mode 1091c may use a resistor R 1093c and current sources 1097e-f along with mixed signals 1089a-b to produce a voltage output signal 1095c. In this example, a mixed signal I 1089a is input with a mixed signal I⁻ 1089b across a resistor R 1093c to produce a DSB voltage output (Vₒᵤₜ) 1095c signal. The voltage output 1095c in DSB mode 1091c may be expressed as Vₒᵤₜ=[I−I⁻]*R. The voltage outputs 1095a-c in LSB, USB and DSB modes 1091a-c may represent the mixer/adder module 819 output signal(s) 825.

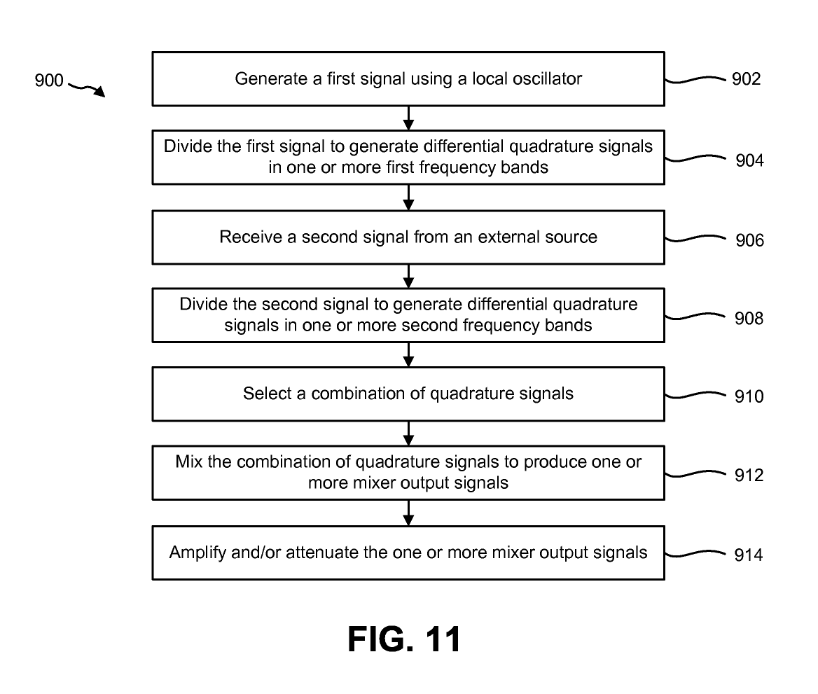

FIG. 11 is a flow diagram illustrating one configuration of a method 900 for generating signals for a built-in self test. A DUT 104 may generate 902 a first signal (e.g., VCO_IN) 542 using a local oscillator (e.g., frequency synthesizer) 544. The DUT 104 may divide 904 the first signal 542 to generate differential quadrature signals (i.e., I, I⁻, Q, Q⁻) in one or more first frequency bands (e.g., frequency bands 890, 892). The DUT 104 may receive 906 a second signal (e.g., TCXO_IN) 230 from an external source (e.g., ATE 102). The DUT 104 may divide 908 the second signal 230 to generate differential quadrature signals (i.e., I, I⁻, Q, Q⁻) in one or more second frequency bands (e.g., auxiliary outputs 801, main outputs 817). The DUT 104 may select 910 a combination of quadrature signals. For example, multiplexer A 896a may select quadrature signals from a frequency band 890, 892 or the auxiliary outputs 801 as output signals 815a-d (e.g., using selection signal A 894a). Additionally, multiplexer B 896b may select signals from a divider 805 as main outputs 817a-d. The DUT 104 may mix 912 the combination of quadrature signals (e.g., multiplexer A outputs 815a-d and main outputs 817a-d) to produce one or more mixer/adder module output signals (e.g., mixer/adder module outputs A and/or B 825a-b). As discussed above, the combination of mixed quadrature signals may or may not also be summed depending on the type of signal (LSB, USB, DSB) desired. The DUT 104 may amplify and/or attenuate 914 the one or more mixer/adder module 819 output signals (e.g., 825a-b) to generate test signals 829a-b. The test signals 829a-b may be applied to one or more circuits under test 216. It should be noted that if no amplification or attenuation are needed for a particular test signal, the mixer/adder module outputs 825a-b may be the test signals 829a-b without amplification and/or attenuation applied.

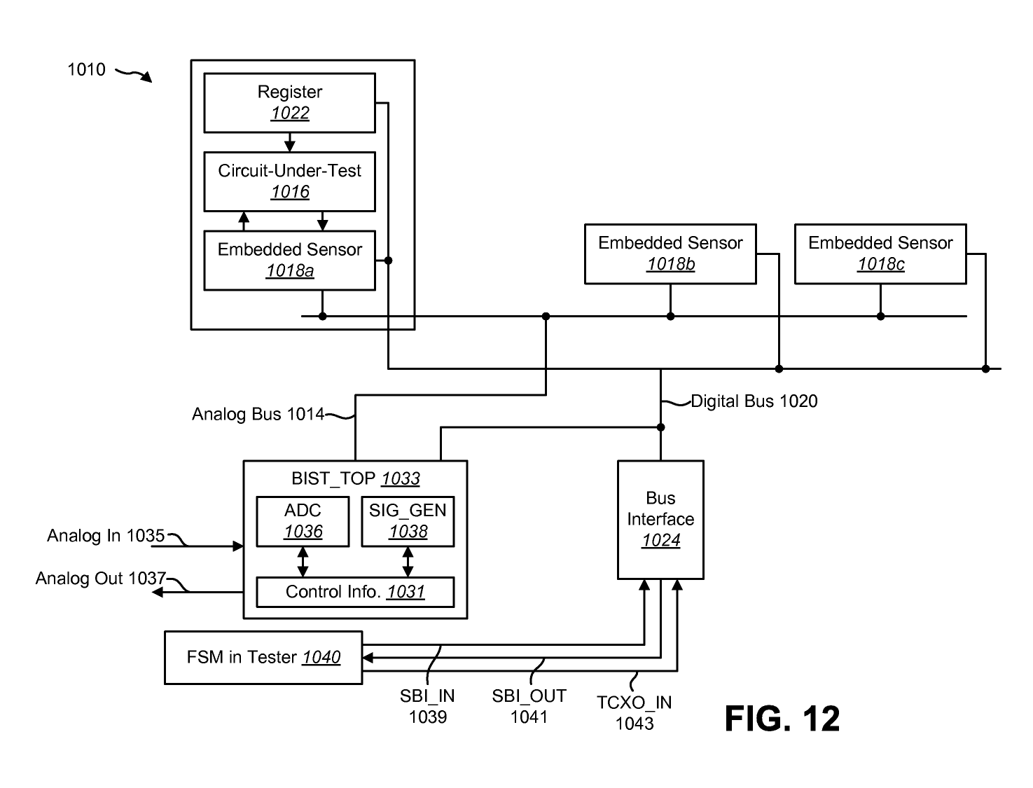

FIG. 12 is a block diagram illustrating a BiST system 1010. The BiST system 1010 may include a bus interface 1024. The bus interface 1024 may allow for external access to the BiST system 1010 by an ATE 102 via a digital bus 1020. The bus interface 1024 may be a serial bus interface (SBI) slave. An FSM in the tester 1040 may send communications to the bus interface 1024 through an SBI_IN 1039 input and receive communications from the bus interface 1024 through an SBI_OUT 1041 output. The FSM in the tester 1040 may also input a clock signal to the BiST system 1010. In one configuration, the FSM in the tester 1040 may input a TCXO_IN 1043 to the bus interface 1024.

The BiST system 1010 may include a central controller. The central controller may be referred to as BiST_TOP 1033. The central controller may communicate with the bus interface 1024 via a digital bus 1020. The digital bus 1020 may include address information, data, and clock (CLK) signals. The central controller may include control information 1031 for the central controller. For example, the central controller may include control information 1031 for controlling a signal generator 1038 and an ADC 1036. The central controller may include a signal generator 1038. The signal generator 1038 may generate analog and/or digital signals for probing a circuit-under-test 1016. The central controller may also include an ADC 1036. The controller may use the ADC 1036 to convert received analog signals to digital signals for transmission to an external ATE 102.

The BiST_TOP 1033 may receive analog in signals 1035 and send analog out signals 1037. The analog in and analog out signals 1035, 1037 may be used for debugging the BiST_TOP 1033.

The central controller may communicate with one or more embedded sensors 1018a-c. The central controller may communicate with the embedded sensors 1018 via an analog bus 1014. The analog bus 1014 may also be referred to as the BiST bus. The central controller may send signals generated by the signal generator 1038 to the embedded sensors 1018 via the analog bus 1014. The controller may also receive signal responses from the embedded sensors 1018 via the analog bus 1014. The controller may also communicate with the embedded sensors 1018 via the digital bus 1020. The central controller may send digital controls to the embedded sensors 1018 via the digital bus 1020.

The central controller may send digital controls to the embedded sensors 1018 through a register 1022. The register 1022 may be an SBI register. The register 1022 may store bits of information such that the information can be read out simultaneously. For example, the register 1022 may include instructions for simultaneously opening and closing switches on the embedded sensors 1018.

The embedded sensors 1018 may provide an array of connections to various nodes on integrated circuits 1016. Thus, an embedded sensor 1018 may provide the ability to probe certain nodes on an integrated circuit 1016 and simultaneously measure the response from other nodes on the integrated circuit 1016. The array of sensors may convert all DC/RF measurements to equivalent DC levels. Because the measured parameter is a DC voltage, a low bandwidth ADC 1036 may be sufficient for the measurements. Because the output of each embedded sensor 1018 is a DC level, more sensors can be added to the array of sensors without adversely impacting the performance of the BiST system 1010.

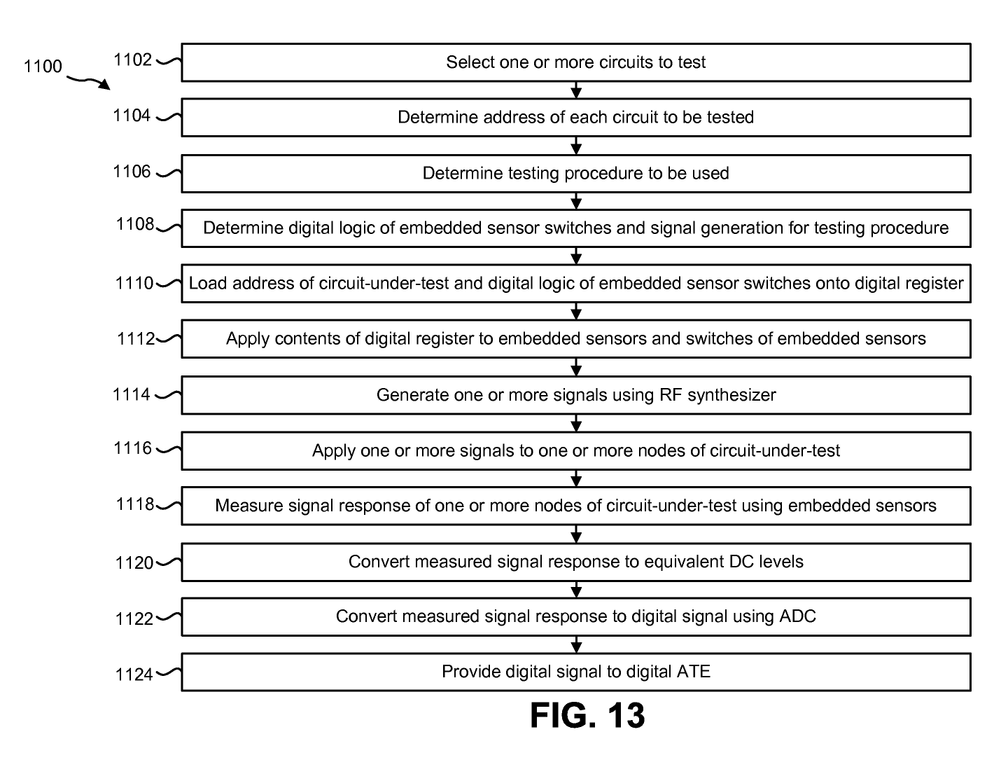

FIG. 13 is a flow diagram illustrating another method 1100 for providing a BiST of mixed signal circuitry. The method 1100 may be performed by a BiST system 1010. The BiST system 1010 may first select 1102 one or more integrated circuits 1016 to be tested. For example, the BiST system 1010 may select 1102 the integrated circuits 1016 for which a particular test is appropriate. The integrated circuits 1016 to be tested may be selected by a central controller on the BiST system 1010. Alternatively, the integrated circuits 1016 to be tested may be selected by the ATE 102.

The BiST system 1010 may determine 1104 the address 332 of each integrated circuit 1016 to be tested. The BiST system 1010 may then determine 1106 the testing procedure to be used. For example, testing procedures may include functional (or parametric) testing, power source current monitoring, direct current (DC) testing, and oscillating frequency testing.

The BiST system 1010 may next determine 1108 the digital logic of switches within embedded sensors 1018 and the appropriate signal generation for the determined testing procedure. For example, a particular testing procedure may input a sinusoidal signal to a particular node within the circuit-under-test 1016. Because an embedded sensor 1018 may provide a connection to multiple nodes with the circuit-under-test 1016, it is important that the generated signal only be applied to the appropriate nodes within the circuit-under-test 1016. By instructing the embedded sensor 1018 to open certain switches and close others, the signal generation can be applied to the appropriate nodes within the circuit-under-test 1016. Each node within the circuit-under-test 1016 receiving signal generation from the signal generator 1038 may receive the same signal generation from the signal generator 1038. Alternatively, each node within the circuit-under-test 1016 receiving signal generation from the signal generator 1038 may receive unique signals. For example, a first node within the circuit-under-test 1016 may receive a square wave signal and a second node within the circuit-under-test 1016 may receive a sinusoidal wave signal.

The BiST system 1010 may load 1110 the address 332 of the circuit-under-test 1016 and the digital logic corresponding to each of the switches onto a register 1022. For example, the register 1022 may be a digital register such as an SBI register. The BiST system 1010 may then apply 1112 the contents of the register 1022 to the embedded sensors 1018 and/or the switches of the embedded sensors 1018. The BiST system 1010 may next generate 1114 one or more signals using a frequency synthesizer. The BiST system 1010 may apply 1116 the one or more signals to the one or more nodes of the circuit-under-test 1016 using the embedded sensors 1018. The embedded sensors 1018 may measure 1118 the signal response of one or more nodes of the circuit-under-test 1016 using the embedded sensors 1018. The embedded sensors 1018 may convert 1120 the measured signal response to equivalent DC levels. The embedded sensors 1018 may convert 1120 the measured signal response to equivalent DC levels using an envelope detector. Envelope detectors are discussed in more detail below in relation to FIG. 14.

The BiST system 1010 may convert 1122 the measured signal response to a digital signal using an ADC 1036. The BiST system 1010 may then provide 1124 the digital signal to a digital ATE 102. The BiST system 1010 may provide 1124 the digital signal to the digital ATE 102 via the digital bus 1020, the bus interface 1024, and the SBI_OUT 1041. Thus, outputs from the ADC 1036 may be provided to the digital ATE 102 via the bus interface 1024.

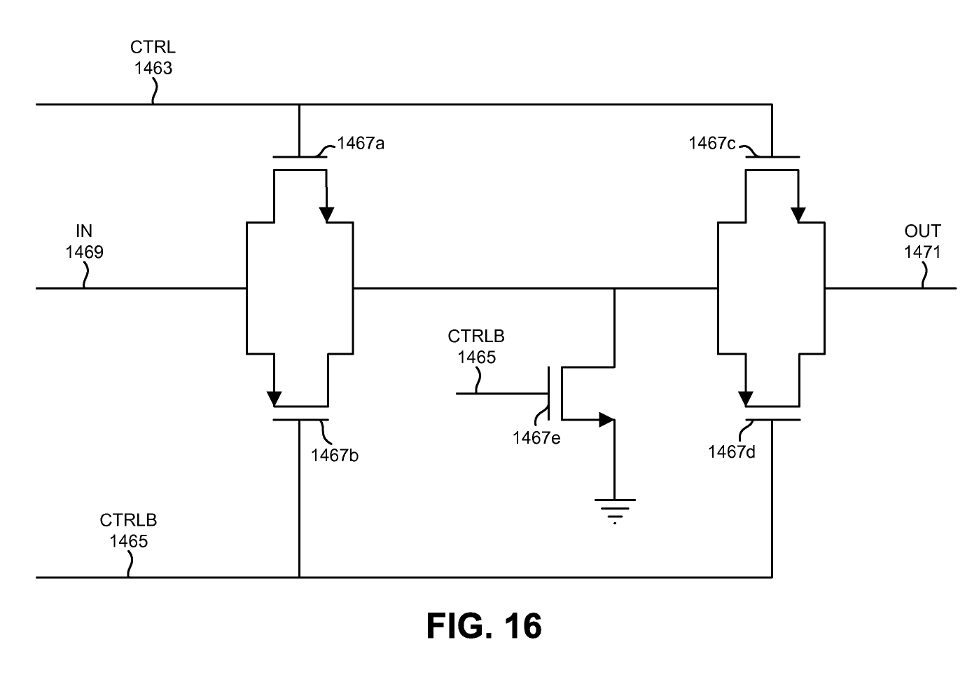

FIG. 14 is a block diagram illustrating an embedded sensor 1218 for use in the present systems and methods. An embedded sensor 1218 may include one or more switches. Each of the switches may provide a connection to a node 1245 within a circuit-under-test 1216. The switches are discussed in further detail below in relation to FIG. 16.

Each switch may have an address 334 associated with the switch. For example, a first switch 1251a may have a first address IS1, a second switch 1251b may have a second address IS2, and an Nth switch 1251n may have an address ISN. A switch may provide stimuli 1247 and/or receive responses 1249 from nodes 1245a-f within the circuit-under-test 1216. In the figure, a first set of switches 1251a-n is shown operating as stimuli 1247 and a second set of switches 1253a-n is shown operating to receive responses 1249. However, a switch may be used for both stimulating the circuit-under-test 1216 and receiving responses from the circuit-under-test 1216. Alternatively, a different set of switches may be used for stimulating the circuit-under-test 1216 than for receiving responses from the circuit-under-test 1216.

A switch 1251 used for stimulating the circuit-under-test 1216 may be connected to the analog bus 1014. A switch 1251 may receive 1257 stimulus signals from a signal generator 1038 via the analog bus 1014. If the switch 1251 is in the closed or ‘on’ position, the switch 1251 may apply the stimulus signals to a node 1245 within the circuit-under-test 1216. If the switch 1251 is in the open or ‘off’ position, the switch 1251 may refrain from applying the stimulus signals to a node 1245 within the circuit-under-test 1216.

A switch may be connected to the digital bus 1020. The digital bus 1020 may allow each switch to receive instructions from a register 1022. For example, an SBI register 1259 may instruct some of the switches to operate in the open or ‘off’ position while simultaneously instructing other switches to operate in the closed or ‘on’ position.

A switch 1253 used for receiving signal responses 1249 from the circuit-under-test 1216 may also be connected to the analog bus 1014. A switch 1253 used for receiving responses 1249 from the circuit-under-test 1216 may receive a signal response 1249 from a node 1245 within the circuit-under-test 1216. If the switch 1253 is in the closed or ‘on’ position, the switch 1253 may send the signal response 1249 to an envelope detector 1255. An envelope detector 1255 may receive a signal response with an input amplitude, and the envelope detector 1255 may output a DC voltage. The envelope detector 1255 may thus perform the step of converting a measured signal response 1249 to equivalent DC levels, as discussed above in relation to FIG. 13. The output of the envelope detector 1255 may then be sent 1261 to an ADC 1036 via the analog bus 1014.

In one configuration, one or more of the switches 1253 may bypass the envelope detector 1255. For example, the switch 1253n used for receiving signal responses 1249 from the circuit-under-test 1216 referred to as OSM may send 1261 received signal responses 1249 directly to the ADC 1036 via the analog bus 1014, provided that the switch 1253n is in the closed or ‘on’ position.

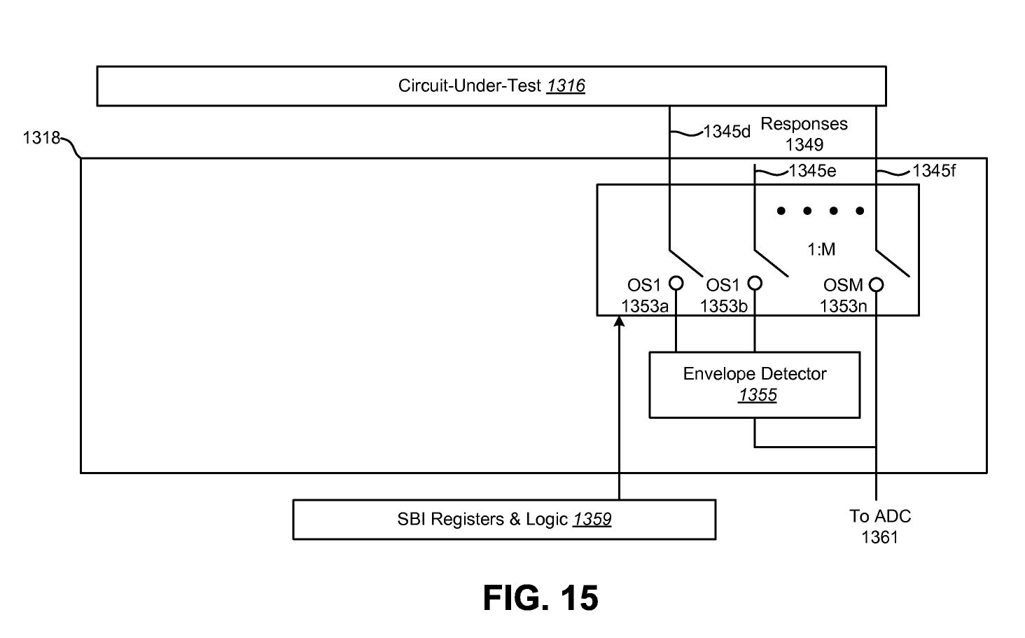

FIG. 15 is a block diagram illustrating another embedded sensor 1318 for use in the present systems and methods. An embedded sensor 1318 may include one or more switches 1353a-n for receiving signal responses 1349 from a circuit-under-test 1316. The switches 1353 may be connected to a digital bus 1020. The digital bus 1020 may allow each of the switches 1353 to receive instructions and digital logic from a register 1359. For example, an SBI register may instruct some of the switches 1353 to operate in the open or ‘off’ position while simultaneously instructing other switches 1353 to operate in the closed or ‘on’ position.

Each switch 1353 may also be connected to an analog bus 1014. A switch 1353 may receive signal responses 1349 from a node 1345d-f within the circuit-under-test 1316. If the switch 1353 is in the closed or ‘on’ position, the switch 1353 may send the signal responses to an envelope detector 1355 for conversion of the measured signal response to equivalent DC levels. The output of the envelope detector 1355 may then be sent 1361 to an ADC 1036 via the analog bus 1014. Alternatively, the switches 1353 may bypass the envelope detector 1355 by sending 1361 the measured signal response directly to the ADC 1036 via the analog bus 1014. If a switch 1353 is in the open or ‘off’ position, the switch 1353 may not relay received signal responses 1349 to the analog bus 1014.

FIG. 16 is a circuit diagram illustrating a switch for use in an embedded sensor 1218. The switch may have an input IN 1469 and an output OUT 1471. In one configuration, the input IN 1469 may be tied to a circuit-under-test 1216 and the output OUT 1471 may be tied to an envelope detector 1255. In another configuration, the input IN 1469 may be tied to an analog bus 1014 and the output OUT 1471 may be tied to a circuit-under-test 1216.

The switch may receive digital control signals CTRL 1463 and CTRLB 1465. CTRLB 1465 may be complementary with CTRL 1463 such that when CTRL 1463 has a high voltage, CTRLB 1465 has a low voltage and when CTRL 1463 has a low voltage, CTRLB 1465 has a high voltage. CTRL 1463 and CTRLB 1465 may be received by the switch from a register 1022 via the digital bus 1020. The switch may also include multiple transistors 1467a-e connected between CTRL 1463 and CTRLB 1465 in a low resistance path. When CTRL 1463 is raised to a high voltage, CTRLB 1465 has a corresponding low voltage. Thus, when CTRL 1463 is raised to a high voltage, transistors 1467a and 1467c are in the closed or ‘on’ position and the input IN 1469 signal flows to the output OUT 1471. Likewise, when CTRLB 1465 has a low voltage, transistors 1467b and 1467d are in the closed or ‘on’ position and the input IN 1469 signal flows to the output OUT 1471. When CTRLB 1465 has a high voltage and CTRL 1463 has a low voltage, transistors 1467a-d are in the open or ‘off’ position and there is no conduction between the input IN 1469 and the output OUT 1471 and thus no signal flows from IN 1469 to OUT 1471.

The switch may include an NMOS transistor 1467e tied between an internal node of the switch and ground. The transistor 1467e may be used to pull the internal node to ground. If routing a high frequency signal from IN 1469 to OUT 1471, it may be necessary that there is zero coupling between IN 1469 and OUT 1471 when the transistors 1467a-d are in the open or ‘off’ position. Thus, even if there is a feedthrough signal through the transistors 1467a and 1467b to the internal node when the transistors 1467a and 1467b are closed, the feedthrough signal will be sent to ground. In other words, transistor 1467e will be closed or ‘on’ whenever CTRLB 1465 is high and CTRL 1463 is low.

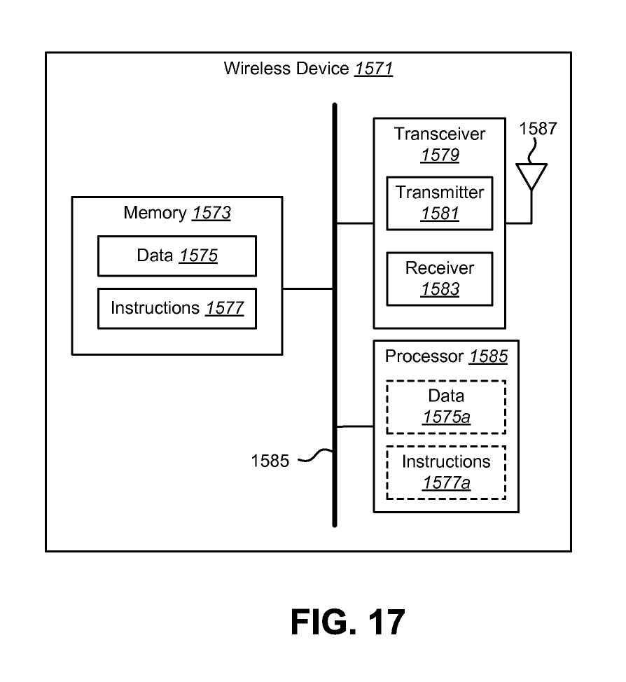

FIG. 17 illustrates certain components that may be included within a wireless device 1571. The wireless device 1571 may be a mobile device/station or a base station. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc. The present systems and methods may be used on an integrated circuit 106 that may be part of a wireless device 1571. Additionally, the present systems and methods may be used on an integrated circuit 106 that may be an electronic device that is not a wireless device 1571. However, the electronic device block diagram and components would be similar to the wireless device 1571 of FIG. 17 except that the electronic device may not have a transceiver 1579.

The wireless device 1571 includes a processor 1585. The processor 1585 may be a general purpose single- or multi-chip microprocessor (e.g., an ARM), a special purpose microprocessor (e.g., a digital signal processor (DSP)), a microcontroller, a programmable gate array, etc. The processor 1585 may be referred to as a central processing unit (CPU). Although just a single processor 1585 is shown in the wireless device 1571 of FIG. 17, in an alternative configuration, a combination of processors (e.g., an ARM and DSP) could be used.

The wireless device 1571 also includes memory 1573. The memory 1573 may be any electronic component capable of storing electronic information. The memory 1573 may be embodied as random access memory (RAM), read only memory (ROM), magnetic disk storage media, optical storage media, flash memory devices in RAM, on-board memory included with the processor, EPROM memory, EEPROM memory, registers, and so forth, including combinations thereof.

Data 1575 and instructions 1577 may be stored in the memory 1573. The instructions 1577 may be executable by the processor 1585 to implement the methods disclosed herein. Executing the instructions 1577 may involve the use of the data 1575 that is stored in the memory 1573. When the processor 1585 executes the instructions 1577, various portions of the instructions 1577a may be loaded onto the processor 1585, and various pieces of data 1575a may be loaded onto the processor 1585.

The wireless device 1571 may also include a transmitter 1581 and a receiver 1583 to allow transmission and reception of signals to and from the wireless device 1571. The transmitter 1581 and receiver 1583 may be collectively referred to as a transceiver 1579. An antenna 1587 may be electrically coupled to the transceiver 1579. The wireless device 1571 may also include (not shown) multiple transmitters, multiple receivers, multiple transceivers and/or multiple antenna.

The various components of the wireless device 1571 may be coupled together by one or more buses, which may include a power bus, a control signal bus, a status signal bus, a data bus, etc. For the sake of clarity, the various buses are illustrated in FIG. 17 as a bus system 1585.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of computer-readable or processor-readable media such as random access memory (RAM), read-only memory (ROM), non-volatile random access memory (NVRAM), programmable read-only memory (PROM), erasable programmable read only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in hardware, software, firmware, or any combination thereof. If implemented in software, the functions may be stored as one or more instructions on a processor-readable or computer-readable medium. The terms “computer-readable medium,” “computer-program product” or “processor-readable medium” refers to any available medium that can be accessed by a computer or processor. By way of example, and not limitation, such a medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIGS. 11 and 13, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit with Built-in Self Test (BiST), comprising:
a signal generator on the integrated circuit, wherein the signal generator is used to perform a BiST on the integrated circuit; and
a local oscillator on the integrated circuit used by the signal generator to generate one or more test signals used to perform the BiST on the integrated circuit.

2. The integrated circuit of claim 1, wherein the local oscillator comprises a frequency synthesizer used for functions other than BiST functions on the integrated circuit.

3. The integrated circuit of claim 1, wherein the local oscillator comprises a radio frequency (RF) synthesizer used for RF transceiver functions.

4. The integrated circuit of claim 1, wherein the signal generator comprises one or more frequency dividers.

5. The integrated circuit of claim 4, wherein the one or more frequency dividers generate differential quadrature signals (I, I⁻, Q, Q⁻) in one or more frequency bands.

6. The integrated circuit of claim 4, wherein the one or more frequency dividers comprises a high frequency divider array and a low frequency divider array, wherein the high frequency divider array divides the frequency of a local oscillator signal and the low frequency divider array divides the frequency of an external signal, wherein the local oscillator signal is at a higher frequency than the external signal.

7. The integrated circuit of claim 4, wherein the signal generator further comprises one or more mixers and a summer.

8. The integrated circuit of claim 7, wherein the one or more mixers mix two or more signals to generate one or more test signals.

9. The integrated circuit of claim 8, wherein the two or more signals mixed are selected from a group consisting of one or more signals based on a local oscillator signal and one or more signals based on an external signal.

10. The integrated circuit of claim 9, wherein the external signal is a digital clock reference signal.

11. The integrated circuit of claim 9, wherein one or more of the local oscillator signals are divided in frequency.

12. The integrated circuit of claim 9, wherein one or more of the external signals are divided in frequency.

13. The integrated circuit of claim 8, wherein the two or more signals to be mixed are selected by one or more multiplexers included in the integrated circuit.

14. The integrated circuit of claim 8, wherein the amplitude of the one or more test signals is adjusted by an amplifier/attenuator module included in the integrated circuit.

15. The integrated circuit of claim 8, wherein the two or more signals are selected and mixed in order to produce frequency variation in the one or more test signals.

16. The integrated circuit of claim 15, wherein the frequency variation is a frequency sweep over a given range of frequencies.

17. The integrated circuit of claim 8, wherein the two or more signals are selected and mixed in order to produce a frequency offset from the local oscillator signal in the one or more test signals.

18. The integrated circuit of claim 17, wherein the frequency offset in the one or more test signals is used to conduct down-conversion measurements.

19. The integrated circuit of claim 14, wherein the amplitude of the one or more test signals is varied to produce an amplitude sweep in the one or more test signals, wherein the amplitude sweep is selected from the group consisting of a linear amplitude sweep and a logarithmic amplitude sweep.

20. The integrated circuit of claim 14, wherein the amplitude of the one or more test signals is varied to produce an offset in differential outputs between two or more test signals.

21. The integrated circuit of claim 20, wherein the offset in differential outputs between the two or more test signals is used to measure one or more circuit imbalances.

22. The integrated circuit of claim 8, wherein the two or more signals are selected and mixed in order to produce test signals that are two-tone signals.

23. The integrated circuit of claim 8, wherein the one or more test signals are used to conduct third-order input intercept point (IIP3) measurements.

24. The integrated circuit of claim 8, wherein the two or more signals are selected and mixed in order to generate a test signal selected from the group consisting of: an upper sideband (USB) signal, a lower sideband (LSB) signal, a double sideband signal (DSB) and a double sideband-suppressed carrier (DSB-SC) signal.

25. The integrated circuit of claim 8, wherein the one or more test signals are differential output signals.

26. A method for generating signals for a Built-in Self Test (BiST), comprising:
generating, on an integrated circuit, a local oscillator signal;
receiving an external signal; and
mixing, on the integrated circuit, two or more signals to generate one or more test signals for a BiST.

27. The method of claim 26, further comprising dividing, on the integrated circuit, the frequency of the local oscillator signal and the external signal into one or more frequency bands.

28. The method of claim 26, further comprising selecting, on the integrated circuit the two or more signals for mixing to generate one or more test signals.

29. The method of claim 28, wherein the two or more signals for mixing comprise differential quadrature signals (I, I⁻, Q, Q⁻).

30. The method of claim 28, further comprising varying, on the integrated circuit, the amplitude of the one or more test signals.

31. The method of claim 26, wherein the local oscillator comprises a radio frequency (RF) synthesizer used for RF transceiver functions.

32. The method of claim 26, wherein the external signal is a digital clock reference signal.

33. The method of claim 26, wherein the local oscillator signal is at a higher frequency than the external signal.

34. The method of claim 28, wherein the two or more signals are selected and mixed in order to produce frequency variation in the one or more test signals.

35. The method of claim 34, wherein the frequency variation is a frequency sweep over a given range of frequencies.

36. The method of claim 28, wherein the two or more signals are selected and mixed in order to produce a frequency offset from the local oscillator signal in the one or more test signals.

37. The method of claim 36, wherein the frequency offset in the one or more test signals is used to conduct down-conversion measurements.

38. The method of claim 30, wherein the amplitude of the test signals are varied to produce an amplitude sweep in the one or more test signals, wherein the amplitude sweep is selected from the group consisting of a linear amplitude sweep and a logarithmic amplitude sweep.

39. The method of claim 30, wherein the amplitude of the one or more test signals are varied in order to produce an offset in differential outputs between two or more of the test signals.

40. The method of claim 39, wherein the offset in differential outputs between the two or more test signals is used to measure one or more circuit imbalances.

41. The method of claim 28, wherein the two or more signals are selected and mixed in order to produce test signals that are two-tone signals.

42. The method of claim 28, wherein the test signals are used to conduct third-order input intercept point (IIP3) measurements.

43. The method of claim 28, wherein the two or more signals are selected and mixed in order to generate a signal selected from the group consisting of: an upper sideband (USB) signal, a lower sideband (LSB) signal, a double sideband signal (DSB) and a double sideband-suppressed carrier (DSB-SC) signal.

44. The method of claim 26, wherein the one or more test signals are differential output signals.

45. A computer-program product for generating signals for a Built-in Self Test (BiST), the computer-program product comprising a non-transitory computer-readable medium having instructions thereon, the instructions comprising:
code for generating a local oscillator signal;
code for receiving an external signal; and
code for mixing two or more signals to generate one or more test signals.

46. The computer-program product of claim 45, wherein the instructions further comprise code for varying the amplitude of the one or more test signals.

47. The computer-program product of claim 45, wherein the instructions further comprise code for varying the frequency of the one or more test signals.

48. An apparatus for generating signals for a Built-in Self Test (BiST), comprising:
means for generating a local oscillator signal;
means for receiving an external signal; and
means for mixing two or more signals to generate one or more test signals.

49. The apparatus of claim 48, further comprising means for varying the amplitude of the one or more test signals and means for varying the frequency of the one or more test signals.
